(19) United States
(12) Patent Application Publication
(10) Pub. No.: US 2026/0227557 A1
(43) Pub. Date: Aug. 6, 2026

(54) LAMINATE AND DISPLAY DEVICE

(71) Applicant: FUJIFILM Corporation, Tokyo (JP)

(72) Inventor: Hiroyuki OKUSA, Minamiashigara-shi (JP)

(73) Assignee: FUJIFILM Corporation, Tokyo (JP)

(21) Appl. No.: 19/653,172

(22) Filed: Apr. 21, 2026

Related U.S. Application Data
(63) Continuation of application No. PCT/JP2024/037371, filed on Oct. 21, 2024.

(30) Foreign Application Priority Data
Dec. 7, 2023 (JP) 2023-206668

(51) Int. Cl. G02B 5/30

(52) U.S. Cl. CPC G02B 5/3016

(57) ABSTRACT

A laminate includes a light-absorbing anisotropic layer and a pressure-sensitive adhesive layer adjacent to at least one surface of the anisotropic layer. The anisotropic layer contains a dichroic substance having a molecular weight of 1,000 or less. The adhesive layer has an indentation modulus of 0.4 MPa to 6.0 MPa and is configured to limit low-molecular-weight components. The adhesive layer either excludes such components or contains 1.0% by mass or less of low-molecular-weight components having Hansen solubility parameters within a predetermined range. A display device including the laminate is also provided, achieving improved fissure resistance, adhesiveness, and durability.

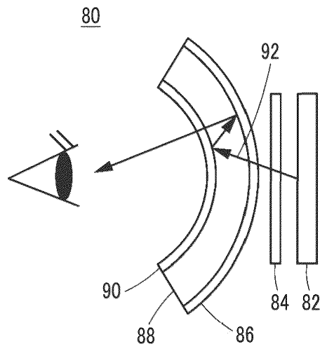

### CROSS-REFERENCE TO RELATED APPLICATIONS

This application is a Continuation of PCT International Application No. PCT/JP2024/037371 filed on Oct. 21, 2024, which claims priority under 35 U.S.C. § 119(a) to Japanese Patent Application No. 2023-206668 filed on Dec. 7, 2023. The above applications are hereby expressly incorporated by reference, in their entirety, into the present application.

### BACKGROUND OF THE INVENTION

### 1. Field of the Invention

The present invention relates to a laminate and a display device.

### 2. Description of the Related Art

In the related art, devices which are operated by different principles for each function have been used in a case where an attenuation function, a polarization function, a scattering function, a shielding function, or the like is required in relation to irradiated light including laser light and natural light. Therefore, products corresponding to the above-described functions have been manufactured through different manufacturing processes for each function.

For example, a linear polarizer or a circular polarizer is used in an image display device (for example, a liquid crystal display device) to control optical rotation or birefringence in display. Further, a circular polarizer is also used even in an organic light emitting diode (OLED) to prevent reflection of external light.

In the related art, iodine has been widely used as a dichroic substance in these polarizers (hereinafter, also referred to as “light-absorbing anisotropic layer”), but it has also been studied to use an organic coloring agent as the dichroic substance instead of the iodine.

In addition, in a case where a laminate having the light-absorbing anisotropic layer is bonded to another member using a pressure sensitive adhesive, it is known that an oxygen impermeable layer (barrier layer) is provided between the light-absorbing anisotropic layer and the pressure sensitive adhesive layer from the viewpoint of ensuring durability of the light-absorbing anisotropic layer (for example, see WO2022/059662A and WO2020/203028A).

### SUMMARY OF THE INVENTION

The present inventors have studied an aspect in which the oxygen impermeable layer is not provided (that is, an aspect in which the light-absorbing anisotropic layer and the pressure sensitive adhesive layer are adjacent to each other) for a laminate having the light-absorbing anisotropic layer described in WO2022/059662A and WO2020/203028A, from the viewpoint of manufacturing suitability, thinning, and the like, and it has been found that, depending on physical property values and components of the pressure sensitive adhesive layer adjacent to the light-absorbing anisotropic layer, any one or more of fissuring resistance, pressure sensitive adhesiveness, and durability may be deteriorated.

Therefore, an object of the present invention is to provide a laminate and a display device, in which all of fissuring resistance, pressure sensitive adhesiveness, and durability are improved.

As a result of intensive studies to achieve the above-described object, the present inventors have found that, by providing, as a pressure sensitive adhesive layer provided adjacent to at least one surface of a light-absorbing anisotropic layer, a pressure sensitive adhesive layer having an indentation modulus within a predetermined range and satisfying predetermined conditions regarding a low-molecular-weight component having a molecular weight of 1,000 or less, a laminate in which all of fissuring resistance, pressure sensitive adhesiveness, and durability are improved is obtained, and have completed the present invention.

That is, the present inventors have found that the above-described problems can be solved by the following configurations.

[1]A laminate comprising:
a light-absorbing anisotropic layer; and
a pressure sensitive adhesive layer provided adjacent to at least one surface of the light-absorbing anisotropic layer,
in which the light-absorbing anisotropic layer contains a dichroic substance having a molecular weight of 1,000 or less,
an indentation modulus of the pressure sensitive adhesive layer is 0.4 MPa to 6.0 MPa, and
the pressure sensitive adhesive layer satisfies the following condition 1 or condition 2 with regard to a low-molecular-weight component having a molecular weight of 1,000 or less,
the condition 1: the pressure sensitive adhesive layer does not contain the low-molecular-weight component,
the condition 2: in a case where the pressure sensitive adhesive layer contains the low-molecular-weight component, a content of the low-molecular-weight component satisfying the following expression (I) is 1.0% by mass or less with respect to a mass of the pressure sensitive adhesive layer,

$$A < B \qquad ( I )$$

in the expression (I), A represents a distance between a Hansen solubility parameter of a matrix component in the light-absorbing anisotropic layer and a Hansen solubility parameter of the low-molecular-weight component in the pressure sensitive adhesive layer, and B represents a distance between a Hansen solubility parameter of a matrix component in the pressure sensitive adhesive layer and the Hansen solubility parameter of the low-molecular-weight component in the pressure sensitive adhesive layer.
[2] The laminate according to [1], in which the matrix component of the light-absorbing anisotropic layer is a liquid crystal compound.
[3] The laminate according to [1] or [2], in which the Hansen solubility parameter of the matrix component in the light-absorbing anisotropic layer is 18 or more.
[4] The laminate according to any one of [1] to [3], in which the matrix component in the pressure sensitive adhesive layer is an acrylic or methacrylic polymer.
[5] The laminate according to any one of [1] to [4], in which the Hansen solubility parameter of the matrix component in the pressure sensitive adhesive layer is 18 or less.
[6] The laminate according to any one of [1] to [5], in which a ratio of an indentation modulus of the light-absorbing anisotropic layer to the indentation modulus of the pressure sensitive adhesive layer is 7,000 or less.
[7]A display device comprising the laminate according to any one of [1] to [6].

According to the present invention, it is possible to provide a laminate and a display device, in which all of fissuring resistance, pressure sensitive adhesiveness, and durability are improved.

### BRIEF DESCRIPTION OF THE DRAWINGS

The FIGURE is a view showing an embodiment of a virtual reality display device which is an example of a display device according to the present invention, and shows an example of a ray of a main image.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, materials that correspond to each component may be used alone or in combination of two or more kinds. Here, in a case where two or more kinds of materials are used in combination for each component, the content of the component refers to the total content of the materials to be combined unless specified otherwise.

In addition, in the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

In the present specification, Re(λ) and Rth(λ) respectively represent an in-plane retardation at a wavelength λ and a thickness-direction retardation at a wavelength λ. Unless otherwise specified, the wavelength λ refers to 550 nm.

In addition, in the present specification, Re(λ) and Rth(λ) are values measured at a wavelength λ using AxoScan OPMF-1 (manufactured by Optoscience. Inc.).

Specifically, by inputting an average refractive index ((nx+ny+nz)/3) and a film thickness (d (μm)) to AxoScan OPMF-1, it is possible to calculate:
a slow axis direction (°),

$$Re ( λ ) = R 0 ( λ ) , and$$

$$Rth ( λ ) = ( ( nx + ny ) / 2 - nz ) \times d$$

are calculated.

R0(λ) is expressed in a numerical value calculated with AxoScan OPMF-1, and means Re(λ).

In the present specification, examples of a substituent (monovalent substituent) include substituents described in the following substituent group A.

In the present specification, “may have a substituent” includes not only an aspect of not having a substituent but also an aspect of having one or more substituents.

### <Substituent Group A>

Examples of the substituent include:
a halogen atom (for example, a fluorine atom, a chlorine atom, or a bromine atom, preferably a chlorine atom or a fluorine atom, and more preferably a fluorine atom);
an alkyl group (a linear, branched, or cyclic alkyl group having preferably 1 to 48 carbon atoms, more preferably 1 to 24 carbon atoms, and particularly preferably 1 to 8 carbon atoms, such as a linear alkyl group having 1 to 6 carbon atoms (for example, a methyl group, an ethyl group, a n-propyl group, a n-butyl group, a n-pentyl group, and a n-hexyl group), a branched alkyl group having 3 to 6 carbon atoms (for example, an isopropyl group, an isobutyl group, a tert-butyl group, a sec-butyl group, a neopentyl group, an isohexyl group, and a 3-methylpentyl group), and a cyclic alkyl group having 3 to 12 carbon atoms (for example, a cyclopropyl group, a cyclopentyl group, a cyclohexyl group, a 1-norbornyl group, and a 1-adamantyl group));
an alkenyl group (an alkenyl group having preferably 2 to 48 carbon atoms and more preferably 2 to 18 carbon atoms, such as a vinyl group, an allyl group, a 1-butenyl group, and a 2-butenyl group);
an alkynyl group (an alkynyl group having preferably 2 to 6 carbon atoms and more preferably 2 to 4 carbon atoms, such as an ethynyl group, a 1-propynyl group, a propargyl group, a 1-butynyl group, and a 2-butynyl group);
an aryl group (an aryl group having preferably 6 to 48 carbon atoms and more preferably 6 to 24 carbon atoms, such as a phenyl group, an oligoaryl group (a naphthyl group or an anthryl group), a phenanthrenyl group, a fluorenyl group, a pyrenyl group, a triphenylenyl group, and a biphenyl group);
a heteroaryl group (a heteroaryl group having preferably 1 to 32 carbon atoms and more preferably 1 to 18 carbon atoms, such as a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group);
an arylalkyl group (an arylalkyl group having preferably 7 to 15 carbon atoms, such as a benzyl group, a phenethyl group, a methylbenzyl group, a phenylpropyl group, a 1-methylphenylethyl group, a phenylbutyl group, a 2-methylphenylpropyl group, a tetrahydronaphthyl group, a naphthylmethyl group, a naphthylethyl group, an indenyl group, a fluorenyl group, an anthracenylmethyl group (an anthrylmethyl group), and a phenanthrenylmethyl group (a phenanthrylmethyl group));
a silyl group (a silyl group having preferably 3 to 38 carbon atoms and more preferably 3 to 18 carbon atoms, such as a trimethylsilyl group, a triethylsilyl group, a tributylsilyl group, a t-butyldimethylsilyl group, and a t-hexyldimethylsilyl group);
a hydroxy group; a cyano group; a nitro group; a morpholino group;
an alkoxy group (an alkoxy group having preferably 1 to 48 carbon atoms and more preferably 1 to 24 carbon atoms, such as a methoxy group, an ethoxy group, a 1-butoxy group, a 2-butoxy group, an isopropoxy group, a t-butoxy group, a dodecyloxy group, and a cycloalkyloxy group (for example, a cyclopentyloxy group or a cyclohexyloxy group));
an aryloxy group (an aryloxy group having preferably 6 to 48 carbon atoms and more preferably 6 to 24 carbon atoms, such as a phenoxy group and a 1-naphthoxy group);
an alkenyloxy group (an alkenyloxy group having preferably 2 to 6 carbon atoms, such as a vinyloxy group, a 1-propenyloxy group, a 2-n-propenyloxy group (an allyloxy group), a 1-n-butenyloxy group, and a prenyloxy group);
a heterocyclic oxy group (a heterocyclic oxy group having preferably 1 to 32 carbon atoms and more preferably 1 to 18 carbon atoms, such as a 1-phenyltetrazol-5-yloxy group and a 2-tetrahydropyranyloxy group);
a silyloxy group (a silyloxy group having preferably 1 to 32 carbon atoms and more preferably 1 to 18 carbon atoms, such as a trimethylsilyloxy group, a t-butyldimethylsilyloxy group, and a diphenylmethylsilyloxy group);
an acyloxy group (an acyloxy group having preferably 2 to 48 carbon atoms and more preferably 2 to 24 carbon atoms, such as an acetoxy group, a pivaloyloxy group, a benzoyloxy group, a dodecanoyloxy group, an acryloyloxy group, and a methacryloyloxy group);
a hydroxyalkyleneoxy group (a hydroxyalkyleneoxy group having preferably 2 to 10 carbon atoms, such as a hydroxyethyleneoxy group);
an alkoxycarbonyloxy group (an alkoxycarbonyloxy group having preferably 2 to 48 carbon atoms and more preferably 2 to 24 carbon atoms, such as an ethoxycarbonyloxy group, a t-butoxycarbonyloxy group, and a cycloalkyloxycarbonyloxy group (for example, a cyclohexyloxycarbonyloxy group));
an aryloxycarbonyloxy group (an aryloxycarbonyloxy group having preferably 7 to 32 carbon atoms and more preferably 7 to 24 carbon atoms, such as a phenoxycarbonyloxy group);
a carbamoyloxy group (a carbamoyloxy group having preferably 1 to 48 carbon atoms and more preferably 1 to 24 carbon atoms, such as an N,N-dimethylcarbamoyloxy group, an N-butylcarbamoyloxy group, an N-phenylcarbamoyloxy group, and an N-ethyl-N-phenylcarbamoyloxy group);
a sulfamoyloxy group (a sulfamoyloxy group having preferably 1 to 32 carbon atoms and more preferably 1 to 24 carbon atoms, such as an N,N-diethylsulfamoyloxy group and an N-propylsulfamoyloxy group);
an alkylsulfonyloxy group (an alkylsulfonyloxy group having preferably 1 to 38 carbon atoms and more preferably 1 to 24 carbon atoms, such as a methylsulfonyloxy group, a hexadecylsulfonyloxy group, and a cyclohexylsulfonyloxy group);
an arylsulfonyloxy group (an arylsulfonyloxy group having preferably 6 to 32 carbon atoms and more preferably 6 to 24 carbon atoms, such as a phenylsulfonyloxy group);
an acyl group (an acyl group having preferably 1 to 48 carbon atoms and more preferably 1 to 24 carbon atoms, such as a formyl group, an acetyl group, an acryloyl group, a methacryloyl group, a pivaloyl group, a benzoyl group, a tetradecanoyl group, and a cyclohexanoyl group);
an alkoxycarbonyl group (an alkoxycarbonyl group having preferably 2 to 48 carbon atoms and more preferably 2 to 24 carbon atoms, such as a methoxycarbonyl group, an ethoxycarbonyl group, an octadecyloxycarbonyl group, a cyclohexyloxycarbonyl group, and a 2,6-di-tert-butyl-4-methylcyclohexyloxycarbonyl group);
an aryloxycarbonyl group (an aryloxycarbonyl group having preferably 7 to 32 carbon atoms and more preferably 7 to 24 carbon atoms, such as a phenoxycarbonyl group);
a carbamoyl group (a carbamoyl group having preferably 1 to 48 carbon atoms and more preferably 1 to 24 carbon atoms, such as a carbamoyl group, an N,N-diethylcarbamoyl group, an N-ethyl-N-octylcarbamoyl group, an N,N-dibutylcarbamoyl group, an N-propylcarbamoyl group, an N-phenylcarbamoyl group, an N-methyl-N-phenylcarbamoyl group, and an N,N-dicyclohexylcarbamoyl group);
an amino group (an amino group having preferably 32 or less carbon atoms and more preferably 24 or less carbon atoms, such as an amino group, a methylamino group, an N,N-dimethylamino group, an N,N-dibutylamino group, a tetradecylamino group, a 2-ethylhexylamino group, and a cyclohexylamino group);
an anilino group (an anilino group having preferably 6 to 32 carbon atoms and more preferably 6 to 24 carbon atoms, such as an anilino group and an N-methylanilino group);
a heterocyclic amino group (a heterocyclic amino group having preferably 1 to 32 carbon atoms and more preferably 1 to 18 carbon atoms, such as a 4-pyridylamino group);
a carboxamide group (a carboxamide group having preferably 2 to 48 carbon atoms and more preferably 2 to 24 carbon atoms, such as an acetamide group, a benzamide group, a tetradecaneamide group, a pivaloylamide group, and a cyclohexaneamide group);
a ureido group (a ureido group having preferably 1 to 32 carbon atoms and more preferably 1 to 24 carbon atoms, such as a ureido group, an N,N-dimethylureido group, and an N-phenylureido group);
an imide group (an imide group having preferably 36 or less carbon atoms and more preferably 24 or less carbon atoms, such as an N-succinimide group and an N-phthalimide group);
an alkoxycarbonylamino group (an alkoxycarbonylamino group having preferably 2 to 48 carbon atoms and more preferably 2 to 24 carbon atoms, such as a methoxycarbonylamino group, an ethoxycarbonylamino group, a t-butoxycarbonylamino group, an octadecyloxycarbonylamino group, and a cyclohexyloxycarbonylamino group);
an aryloxycarbonylamino group (an aryloxycarbonylamino group having preferably 7 to 32 carbon atoms and more preferably 7 to 24 carbon atoms, such as a phenoxycarbonylamino group);
a sulfonamide group (a sulfonamide group having preferably 1 to 48 carbon atoms and more preferably 1 to 24 carbon atoms, such as a methanesulfonamide group, a butanesulfonamide group, a benzenesulfonamide group, a hexadecanesulfonamide group, and a cyclohexanesulfonamide group);
a sulfamoylamino group (a sulfamoylamino group having preferably 1 to 48 carbon atoms and more preferably 1 to 24 carbon atoms, such as an N,N-dipropylsulfamoylamino group and an N-ethyl-N-dodecylsulfamoylamino group);
an azo group (an azo group having preferably 1 to 32 carbon atoms and more preferably 1 to 24 carbon atoms, such as a phenylazo group and a 3-pyrazolylazo group);
an alkylthio group (an alkylthio group having preferably 1 to 48 carbon atoms and more preferably 1 to 24 carbon atoms, such as a methylthio group, an ethylthio group, an octylthio group, and a cyclohexylthio group);
an arylthio group (an arylthio group having preferably 6 to 48 carbon atoms and more preferably 6 to 24 carbon atoms, such as a phenylthio group);
a heterocyclic thio group (a heterocyclic thio group having preferably 1 to 32 carbon atoms and more preferably 1 to 18 carbon atoms, such as a 2-benzothiazolylthio group, a 2-pyridylthio group, and a 1-phenyltetrazolylthio group);
an alkylsulfinyl group (an alkylsulfinyl group having preferably 1 to 32 carbon atoms and more preferably 1 to 24 carbon atoms, such as a dodecanesulfinyl group);
an arylsulfinyl group (an arylsulfinyl group having preferably 6 to 32 carbon atoms and more preferably 6 to 24 carbon atoms, such as a phenylsulfinyl group);
an alkylsulfonyl group (an alkylsulfonyl group having preferably 1 to 48 carbon atoms and more preferably 1 to 24 carbon atoms, such as a methylsulfonyl group, an ethylsulfonyl group, a propylsulfonyl group, a butylsulfonyl group, an isopropylsulfonyl group, a 2-ethylhexylsulfonyl group, a hexadecylsulfonyl group, an octylsulfonyl group, and a cyclohexylsulfonyl group);
an arylsulfonyl group (an arylsulfonyl group having preferably 6 to 48 carbon atoms and more preferably 6 to 24 carbon atoms, such as a phenylsulfonyl group and a 1-naphthylsulfonyl group);
a sulfamoyl group (a sulfamoyl group having preferably 32 or less carbon atoms and more preferably 24 or less carbon atoms, such as a sulfamoyl group, an N,N-dipropylsulfamoyl group, an N-ethyl-N-dodecylsulfamoyl group, an N-ethyl-N-phenylsulfamoyl group, an N-cyclohexylsulfamoyl group, and an N-(2-ethylhexyl)sulfamoyl group);
a phosphonyl group (a phosphonyl group having preferably 1 to 32 carbon atoms and more preferably 1 to 24 carbon atoms, such as a phenoxyphosphonyl group, an octyloxyphosphonyl group, and a phenylphosphonyl group);
a phosphinoylamino group (a phosphinoylamino group having preferably 1 to 32 carbon atoms and more preferably 1 to 24 carbon atoms, such as a diethoxyphosphinoylamino group and a dioctyloxyphosphinoylamino group);
an epoxy group; —NHCOCH₃; —SO₂NHC₂H₄OCH₃; and —NHSO₂CH₃, in which two or more thereof may be combined.

These substituents may be further substituted with these substituents. In addition, in a case of having two or more of the substituents, the substituents may be the same or different from each other. Furthermore, if possible, these substituents may be bonded to each other to form a ring.

### [Laminate]

The laminate according to the embodiment of the present invention is a laminate including a light-absorbing anisotropic layer and a pressure sensitive adhesive layer provided adjacent to at least one surface of the light-absorbing anisotropic layer.

In addition, the light-absorbing anisotropic layer included in the laminate according to the embodiment of the present invention contains a dichroic substance having a molecular weight of 1,000 or less.

In addition, the pressure sensitive adhesive layer included in the laminate according to the embodiment of the present invention is a pressure sensitive adhesive layer in which an indentation modulus is 0.4 to 6.0 MPa, and the following condition 1 or 2 is satisfied with regard to a low-molecular-weight component having a molecular weight of 1,000 or less.

Condition 1: the pressure sensitive adhesive layer does not contain the low-molecular-weight component.

Condition 2: in a case where the pressure sensitive adhesive layer contains the low-molecular-weight component, a content of the low-molecular-weight component satisfying the following expression (I) is 1.0% by mass or less with respect to a mass of the pressure sensitive adhesive layer.

$$A < B \qquad ( I )$$

In the expression (I), A represents a distance between a Hansen solubility parameter of a matrix component in the light-absorbing anisotropic layer and a Hansen solubility parameter of the low-molecular-weight component in the pressure sensitive adhesive layer, and B represents a distance between a Hansen solubility parameter of a matrix component in the pressure sensitive adhesive layer and the Hansen solubility parameter of the low-molecular-weight component in the pressure sensitive adhesive layer.

In the present invention, molecular weights of the dichroic substance and the low-molecular-weight component (both 1,000 or less) can be measured by the following methods, respectively.

### <Dichroic Substance>

The molecular weight of the dichroic substance can be obtained by measuring, by liquid chromatography-mass spectrometry (LC/MS), a solution obtained by dissolving the light-absorbing anisotropic layer or an extract obtained by immersing the light-absorbing anisotropic layer in a solvent; however, the method is not limited to the technique.

### <Low-Molecular-Weight Component>

The molecular weight of the low-molecular-weight component can be obtained by performing gas chromatography-mass spectrometry (GC/MS) measurement, under the following conditions, on a solution obtained by dissolving the pressure sensitive adhesive layer or on an extract obtained by immersing the pressure sensitive adhesive layer in a solvent, and quantification can be performed using the low-molecular-weight component contained in the pressure sensitive adhesive layer as a standard sample; however, the method is not limited to the technique.
GC/MS measurement conditions
Column: DB-5MS (0.25 mmφ×30 m, film thickness 0.25 μm)
Column temperature: 50° C. (0 to 2 min)-10° C./min-320° C. (29 to 40 min)
Carrier gas: He (1.0 mL/min)
Sample injection volume: 0.5 L
Detection: EI-MS

In addition, in the present invention, the indentation modulus of the pressure sensitive adhesive layer refers to a value obtained by measuring an indentation modulus of a surface of a test body (a surface of the pressure sensitive adhesive layer on a side opposite to the light-absorbing anisotropic layer) using a micro-hardness evaluation apparatus (for example, Nano Triboindenter TI-950 manufactured by Bruker) under the following conditions. An indentation modulus of the light-absorbing anisotropic layer, which will be described later, refers to a value obtained by measuring an indentation modulus of a surface of a test body (a surface of the light-absorbing anisotropic layer on the pressure sensitive adhesive layer side) under the same conditions.
Indenter: triangular pyramid diamond indenter (Berkovich indenter, internal angle of indenter: 142.35°, angle between center line and surface: 65.35°)
Maximum indentation depth of indenter: 500 nm
Measurement temperature: 23° C.

In addition, the Hansen solubility parameters (HSP) (hereinafter, also abbreviated as “HSP values”) are obtained by dividing a solubility of a substance into three components (a dispersion element δd, a polarity element δp, and a hydrogen bond element δh) and expressing them in a three-dimensional space. The dispersion element δd represents an effect of a dispersion force, the polarity element δp represents an effect of a dipole-dipole force, and the hydrogen bond element δh represents an effect of a hydrogen bonding force.

In the present invention, values calculated by inputting a structural formula of a compound into HSPiP (Ver. 5.1.08) are adopted as the Hansen solubility parameters. In a copolymer, δd, δp, and δh are calculated using a structural formula in which a bonding portion of each repeating unit is replaced with a hydrogen atom, and values averaged by a mass ratio of copolymer components are adopted. In addition, in a case where the matrix or the like is a three-dimensional crosslinked body of (meth)acrylate, δd, δp, and δh are calculated using a structural formula of each monomer; and in a case where a plurality of monomers are mixed, values averaged by a mass ratio are adopted.

In the present invention, distances represented by A and B in the above expression (I) can be calculated as Ra by introducing δd, δp, and δh calculated for each component into the following expression. δd1, δp1, and δh1 in the following expression are values calculated from the low-molecular-weight component in the pressure sensitive adhesive layer; and δd2, δp2, and δh2 are values calculated from the matrix component in the light-absorbing anisotropic layer when calculating A, and are values calculated from the matrix component in the pressure sensitive adhesive layer in a case of calculating B.

$$Ra = \sqrt{4 {( {δ}_{d 2} - {δ}_{d 1} )}^{2} + {( {δ}_{p 2} - {δ}_{p 1} )}^{2} + {( {δ}_{h 2} - {δ}_{h 1} )}^{2}}$$

In the present invention, as described above, by providing, as the pressure sensitive adhesive layer provided adjacent to at least one surface of the light-absorbing anisotropic layer, a pressure sensitive adhesive layer having an indentation modulus within a range of 0.4 to 6.0 MPa and satisfying the above-described condition 1 or 2 regarding the low-molecular-weight component having a molecular weight of 1,000 or less, a laminate having excellent fissuring resistance, pressure sensitive adhesiveness, and durability is obtained.

The reason why the effect is exhibited is not clear in detail, but the present inventor has presumed as follows.

First, it is known that the pressure sensitive adhesive layer desirably has a high elastic modulus from the viewpoint of ensuring pressure sensitive adhesiveness; however, as shown in Comparative Examples 3 and 4 described later, fissuring occurs in a case where the indentation modulus is more than 6.0 MPa. In addition, as shown in Comparative Example 1 described later, the pressure sensitive adhesiveness is deteriorated in a case where the indentation modulus is less than 0.4 MPa.

In addition, as shown in Comparative Example 2 described later, in a case where the condition 1 and the condition 2 described above are not satisfied regarding the low-molecular-weight component having a molecular weight of 1,000 or less, durability is deteriorated. This is thought to be caused by the dichroic substance contained in the light-absorbing anisotropic layer migrating (flowing out) into the adjacent pressure sensitive adhesive layer. However, the present inventors presume that the cause of the outflow of the dichroic substance is that a low-molecular-weight compound in the pressure sensitive adhesive layer migrates (flows out) into the light-absorbing anisotropic layer before the dichroic substance flows out, thereby increasing fluidity of the light-absorbing anisotropic layer.

Therefore, in the present invention, it is considered that, by setting the indentation modulus of the pressure sensitive adhesive layer within the range of 0.4 to 6.0 MPa, the fissuring resistance and the pressure sensitive adhesiveness are improved.

In addition, it is considered that, by satisfying the above-described condition 1 or 2 with regard to the low-molecular-weight component having a molecular weight of 1,000 or less in the pressure sensitive adhesive layer, the outflow of the low-molecular-weight compound into the light-absorbing anisotropic layer is suppressed; as a result, the outflow of the dichroic substance into the pressure sensitive adhesive layer is suppressed, thereby improving the durability.

Hereinafter, the light-absorbing anisotropic layer and the pressure sensitive adhesive layer included in the laminate according to the embodiment of the present invention will be described in detail.

### [Light-Absorbing Anisotropic Layer]

### <Dichroic Substance>

As described above, the light-absorbing anisotropic layer included in the laminate according to the embodiment of the present invention contains a dichroic substance having a molecular weight of 1,000 or less.

Here, the dichroic substance means a coloring agent having different absorbances depending on the direction.

In addition, the dichroic substance may or may not exhibit liquid crystallinity.

The dichroic substance is not particularly limited, and examples thereof include a visible light absorbing substance (dichroic organic coloring agent and iodine), a light emitting substance (fluorescent substance and phosphorescent substance), an ultraviolet absorbing substance, an infrared absorbing substance, a non-linear optical substance, a carbon nanotube, and an inorganic substance (for example, quantum rod), and known dichroic substances (dichroic coloring agents) of the related art can be used. The above-described visible light absorbing substance preferably has a maximum absorption wavelength in a visible light region.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0014] to [0032] of JP2018-053167A, paragraphs [0014] to [0033] of JP2020-11716A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and paragraphs [0015] to [0038] of WO2021/044843A.

As the dichroic substance, a dichroic azo coloring agent compound is preferable.

The dichroic azo coloring agent compound means an azo coloring agent compound having different absorbances depending on directions. The dichroic azo coloring agent compound may or may not exhibit liquid crystallinity. In a case where the dichroic azo coloring agent compound exhibits liquid crystallinity, the dichroic azo coloring agent compound may exhibit any of nematic liquid crystallinity or smectic liquid crystallinity. The temperature range in which the liquid crystallinity is exhibited is preferably room temperature (approximately 20° C. to 28° C.) to 300° C., and from the viewpoint of handleability and manufacturing suitability, more preferably 50° C. to 200° C.

In the present invention, from the viewpoint of tint adjustment, it is preferable to use at least one coloring agent compound (first dichroic azo coloring agent compound) having a maximal absorption wavelength in a wavelength range of 560 to 700 nm and at least one coloring agent compound (second dichroic azo coloring agent compound) having a maximal absorption wavelength in a wavelength range of 455 nm or more and less than 560 nm.

In the present invention, three or more kinds of dichroic azo coloring agent compounds may be used in combination. For example, from the viewpoint of making color of the light-absorbing anisotropic layer close to black, it is preferable to use the first dichroic azo coloring agent compound, the second dichroic azo coloring agent compound, and at least one coloring agent compound having a maximal absorption wavelength in a wavelength range of 380 nm or more and less than 455 nm (third dichroic azo coloring agent compound) in combination.

In the present invention, from the viewpoint of excellent light fastness of the light-absorbing anisotropic layer, it is preferable to contain two or more kinds of the first dichroic azo coloring agent compounds.

In the present invention, the dichroic azo coloring agent compound preferably has a crosslinkable group.

Examples of the crosslinkable group include a (meth)acryloyl group, an epoxy group, an oxetanyl group, and a styryl group. Among these, a (meth)acryloyl group is preferable.

A content of the dichroic substance is preferably 3% to 90% by mass, more preferably 5% to 70% by mass, and still more preferably 10% to 60% by mass with respect to the mass of the light-absorbing anisotropic layer. In a case where a plurality of dichroic substances are used in combination, it is preferable that the total amount of the plurality of dichroic substances is in the above-described range.

### <Liquid Crystal Compound>

The light-absorbing anisotropic layer included in the laminate according to the embodiment of the present invention preferably contains a liquid crystal compound.

Accordingly, the dichroic substance can be aligned with a higher alignment degree while suppressing precipitation of the above-described dichroic substance.

As the liquid crystal compound, both a high-molecular-weight liquid crystal compound and a low-molecular-weight liquid crystal compound can be used, and from the viewpoint of increasing the alignment degree, a polymer liquid crystal compound is preferable.

In addition, the liquid crystal compound may be contained alone or in combination of two or more kinds thereof, and the high-molecular-weight liquid crystal compound and the low-molecular-weight liquid crystal compound may be used in combination.

Here, the “high-molecular-weight liquid crystal compound” denotes a liquid crystal compound having a repeating unit in the chemical structure. In addition, the liquid crystal compound having a repeating unit in the chemical structure is also referred to as a side chain-type high-molecular-weight liquid crystal compound.

In addition, the “low-molecular-weight liquid crystal compound” refers to a liquid crystal compound not including a repeating unit in a chemical structure.

Examples of the high-molecular-weight liquid crystal compound include thermotropic liquid crystalline polymers described in JP2011-237513A and high-molecular-weight liquid crystal compounds described in paragraphs [0012] to [0042] of WO2018/199096A.

Examples of the low-molecular-weight liquid crystal compound include liquid crystal compounds described in paragraphs [0072] to [0088] of JP2013-228706A. Among these, a liquid crystal compound exhibiting smectic properties is preferable.

Examples of such a liquid crystal compound include those described in paragraphs [0019] to [0140] of WO2022/014340A, the description of which is incorporated herein by reference.

In addition, the liquid crystal compound is preferably a liquid crystal compound which does not exhibit dichroism in the visible light region.

A weight-average molecular weight (Mw) of the high-molecular-weight liquid crystal compound is preferably 2,000 to 300,000 and more preferably 2,000 to 100,000. In a case where the Mw of the high molecular weight liquid crystal compound is within the above range, the high molecular weight liquid crystal compound can be easily handled.

Here, the weight-average molecular weight (Mw) and the number-average molecular weight (Mn) of the high-molecular-weight liquid crystal compound are values measured by a gel permeation chromatography (GPC) method.
Solvent (eluant): N-methylpyrrolidone
Device name: TOSOH HLC-8220GPC
Column: Three items of TOSOH TSKgel Super HZM-H (4.6 mm×15 cm) are connected and used.
Column temperature: 25° C.
Sample Concentration: 0.1% by mass
Flow rate: 0.35 ml/min
Calibration curve: TSK standard polystyrene manufactured by TOSOH Corporation, calibration curves of 7 samples with Mw of 2,800,000 to 1,050 (Mw/Mn=1.03 to 1.06) are used

A content of the liquid crystal compound is preferably 25 to 2,000 parts by mass, more preferably 100 to 1,300 parts by mass, and still more preferably 200 to 900 parts by mass with respect to 100 parts by mass of the content of the above-described dichroic substance. In a case where the content of the liquid crystal compound is within the above-described range, the alignment degree of the dichroic substance is further improved. In a case where a plurality of liquid crystal compounds are used in combination, it is preferable that the total amount of the plurality of liquid crystal compounds is in the above-described range.

In the present invention, the matrix component of the light-absorbing anisotropic layer is preferably a liquid crystal compound.

Here, the matrix component of the light-absorbing anisotropic layer refers to a component having the largest blending amount among components other than the dichroic substance contained in the light-absorbing anisotropic layer.

Therefore, a content of the liquid crystal compound is preferably more than 50% by mass and 90% by mass or less, more preferably 55% to 85% by mass, and still more preferably 60% to 80% by mass with respect to the mass of the light-absorbing anisotropic layer. In a case where a plurality of liquid crystal compounds are used in combination, it is preferable that the total amount of the plurality of liquid crystal compounds is in the above-described range.

In addition, in the present invention, from the viewpoint of promoting moderate phase separation with the hydrophobic dichroic substance and enhancing aligning properties, the HSP value of the matrix component of the light-absorbing anisotropic layer is preferably 18 or more, and more preferably 18 to 26.

The light-absorbing anisotropic layer included in the laminate according to the embodiment of the present invention is preferably a layer in which the alignment state of the above-described dichroic substance and liquid crystal compound is fixed, and is more preferably a layer formed of a composition for forming a light-absorbing anisotropic layer, containing the above-described dichroic substance and liquid crystal compound.

Here, it is preferable that the composition for forming a light-absorbing anisotropic layer contains a surfactant, an alignment agent, a polymerization initiator, a solvent, and the like described later, in addition to the above-described dichroic substance and liquid crystal compound.

### <Surfactant>

As the surfactant, fluorine (meth)acrylate-based polymers described in paragraphs [0018] to [0043] of JP2007-272185A, and polymers having silicon described in paragraphs [0019] to [0073] of WO2023/054164A can be used. Compounds other than these may be used as the surfactant. The surfactant may be used alone or in combination of two or more kinds thereof.

In a case where the composition for forming a light-absorbing anisotropic layer contains a surfactant, a content of the surfactant is preferably 0.01% to 10% by mass and more preferably 0.02% to 5% by mass with respect to a total solid content mass of the composition for forming a light-absorbing anisotropic layer.

### <Alignment Agent>

Examples of the alignment agent include a boronic acid compound and an onium salt. The boronic acid compound functions as a horizontal alignment agent or a vertical alignment agent. In addition, the onium salt functions as a vertical alignment agent. The alignment agents may be used alone or in combination of two or more kinds thereof.

As the boronic acid compound, a compound represented by Formula (30) is preferable.

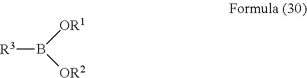

In Formula (30), R¹ and R² each independently represent a hydrogen atom, a substituted or unsubstituted aliphatic hydrocarbon group, a substituted or unsubstituted aryl group, or a substituted or unsubstituted heterocyclic group.

R³ represents a substituent containing a (meth)acryloyl group.

Specific examples of the boronic acid compound include a boronic acid compound represented by General Formula (I) described in paragraphs 0023 to 0032 of JP2008-225281A.

As the boronic acid compound, compounds shown below are also preferable.

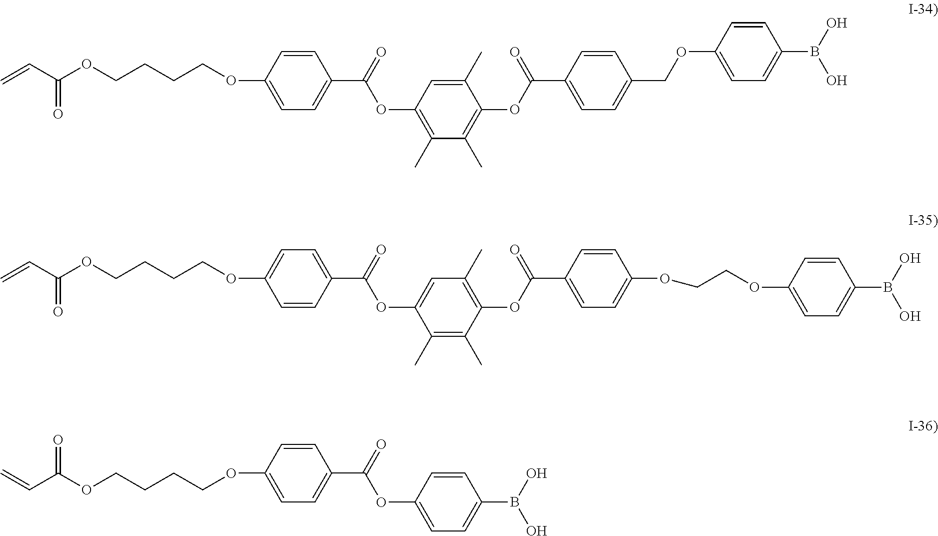 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

Specific examples of the onium salt include onium salts described in paragraphs 0052 to 0058 of JP2012-208397A, onium salts described in paragraphs 0024 to 0055 of JP2008-026730A, and onium salts described in JP2002-37777A.

In a case where the composition for forming a light-absorbing anisotropic layer contains an alignment agent, a content of the alignment agent is preferably 0.01% to 30% by mass and more preferably 0.1% to 10% by mass with respect to the total solid content mass of the composition for forming a light-absorbing anisotropic layer.

### <Polymerization Initiator>

The polymerization initiator is not particularly limited, but a photosensitive compound, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds (paragraph [0065] of JP2016-27384A), and acylphosphine oxide compounds (JP1988-40799B (JP-S63-40799B), JP1993-29234B (JP-H5-29234B), JP1998-95788A (JP-H10-95788A), and JP1998-29997A (JP-H10-29997A)).

As such a photopolymerization initiator, commercially available products can also be used, and examples thereof include Irgacure 184, Irgacure 907, Irgacure 369, Irgacure 651, Irgacure 819, Irgacure OXE-01, and Irgacure OXE-02 manufactured by BASF SE.

The polymerization initiators may be used alone or in combination of two or more kinds thereof.

In a case where the composition for forming a light-absorbing anisotropic layer contains a polymerization initiator, a content of the polymerization initiator is preferably 0.01% to 30% by mass and more preferably 0.1% to 15% by mass with respect to the total solid content mass of the composition for forming a light-absorbing anisotropic layer.

### <Solvent>

Examples of the solvent include organic solvents such as ketones (such as acetone, 2-butanone, methyl isobutyl ketone, cyclopentanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, it is preferable to use an organic solvent and more preferable to use halogenated carbons or ketones from the viewpoint that the effects of the present invention are more excellent.

In a case where the composition for forming a light-absorbing anisotropic layer contains a solvent, a content of the solvent is preferably 70% to 99% by mass, more preferably 83% to 97% by mass, and still more preferably 85% to 95% by mass with respect to the total mass of the composition for forming a light-absorbing anisotropic layer.

### <Manufacturing Method>

A method for manufacturing the light-absorbing anisotropic layer is not particularly limited, but a method (hereinafter, also referred to as “present manufacturing method”) including, in this order, a step of applying the above-described composition for forming a light-absorbing anisotropic layer onto an alignment film to form a coating film (hereinafter, also referred to as “coating film forming step”) and a step of aligning a liquid crystal component contained in the coating film (hereinafter, also referred to as “aligning step”) is preferable.

The liquid crystal component is a component containing not only the liquid crystal compound described above but also a dichroic substance having liquid crystallinity.

Hereinafter, each of the steps will be described.

The coating film-forming step is a step of applying the above-described composition for forming a light-absorbing anisotropic layer onto the alignment film to form a coating film.

The alignment film is easily coated with the composition for forming a light-absorbing anisotropic layer by using the composition for forming a light-absorbing anisotropic layer which contains the above-described solvent or using a liquid-like material such as a melt obtained by heating the composition for forming a light-absorbing anisotropic layer.

Examples of a method of applying the composition for forming a light-absorbing anisotropic layer include known methods such as a roll coating method, a gravure printing method, a spin coating method, a wire bar coating method, an extrusion coating method, a direct gravure coating method, a reverse gravure coating method, a die coating method, a spraying method, and an inkjet method.

The alignment film may be any film as long as it is a film in which the liquid crystal component which can be contained in the composition for forming a light-absorbing anisotropic layer is aligned.

The alignment film can be provided by methods such as rubbing treatment of an organic compound (preferably a polymer) on a film surface, oblique vapor deposition of an inorganic compound, formation of a layer having microgrooves, or accumulation of an organic compound (for example, ω-tricosanoic acid, dioctadecylmethylammonium chloride, or methyl stearate) by the Langmuir-Blodgett method (LB film). Furthermore, an alignment film in which an alignment function is generated by application of an electric field, application of a magnetic field, or irradiation with light is also known. Among these, an alignment film formed by a rubbing treatment is preferable in view of easy control of a pretilt angle of the alignment film, and a photo-alignment film formed by light irradiation is also preferable in view of alignment uniformity in the present invention.

As the photo-alignment film, a photo-alignment film containing an azobenzene coloring agent, polyvinyl cinnamate, or the like is used.

The dichroic substance in the light-absorbing anisotropic layer can be aligned by irradiating a photo-alignment layer with ultraviolet rays in an oblique direction at an angle to the normal direction of the photo-alignment layer, generating anisotropy with an inclination with respect to the normal direction of the photo-alignment layer, and aligning the light-absorbing anisotropic layer thereon.

In addition, a liquid crystal layer in which the liquid crystal compound is hybrid-aligned can also be used as the alignment film.

The aligning step is a step of aligning the liquid crystal component (particularly, the dichroic substance) contained in the coating film. In the aligning step, the dichroic substance is considered to be aligned along the liquid crystal compound aligned by the alignment film.

The aligning step may have a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

The aligning step preferably has a heating treatment. In this manner, the dichroic substance contained in the coating film is further aligned, and the alignment degree of the dichroic substance is further increased.

From the viewpoint of the manufacturing suitability, the heat treatment is performed at a temperature of preferably 10° C. to 250° C. and more preferably 25° C. to 190° C. In addition, the heating time is preferably 1 to 300 seconds and more preferably 1 to 60 seconds.

The aligning step may include a cooling treatment performed after the heating treatment. The cooling treatment is a treatment of cooling the heated coating film to room temperature (20° C. to 25° C.). As a result, the alignment of the dichroic substance contained in the coating film is further fixed, and the alignment degree of the dichroic substance is further increased. The cooling unit is not particularly limited, and the cooling can be performed by a known method.

The light-absorbing anisotropic layer according to the embodiment of the present invention can be obtained by performing the above-described steps.

The present manufacturing method may include a step of curing the light-absorbing anisotropic layer after the above-described aligning step (hereinafter, also referred to as “curing step”).

For example, the curing step is performed by heating and/or light irradiation (exposure). Among these, it is preferable that the curing step is performed by irradiating the light-absorbing anisotropic layer with light.

As a light source used for curing, various light sources for infrared light, visible light, ultraviolet light, or the like can be used, but a light source for ultraviolet light is preferable. In addition, ultraviolet rays may be applied while the light absorption anisotropic film is heated during the curing, or ultraviolet rays may be applied through a filter which transmits only a specific wavelength.

Further, the exposure may be performed under a nitrogen atmosphere. In a case where curing of the light-absorbing anisotropic layer proceeds by radical polymerization, inhibition of the polymerization by oxygen is reduced, and thus the exposure is preferably performed under a nitrogen atmosphere.

The thickness of the light-absorbing anisotropic layer is not particularly limited, but from the viewpoint that the effects of the present invention are more excellent, the thickness is preferably 0.5 to 7 μm, and more preferably 1.0 to 3 μm.

### [Pressure Sensitive Adhesive Layer]

As described above, the laminate according to the embodiment of the present invention includes a pressure sensitive adhesive layer provided adjacent to at least one surface of the light-absorbing anisotropic layer.

In addition, as described above, the pressure sensitive adhesive layer included in the laminate according to the embodiment of the present invention is a pressure sensitive adhesive layer in which an indentation modulus is 0.4 to 6.0 MPa, and the following condition 1 or 2 is satisfied with regard to a low-molecular-weight component having a molecular weight of 1,000 or less.

Condition 1: the pressure sensitive adhesive layer does not contain the low-molecular-weight component.

Condition 2: in a case where the pressure sensitive adhesive layer contains the low-molecular-weight component, a content of the low-molecular-weight component satisfying the following expression (I) is 1.0% by mass or less with respect to a mass of the pressure sensitive adhesive layer.

$$A < B \qquad ( I )$$

In the expression (I), A represents a distance between a Hansen solubility parameter of a matrix component in the light-absorbing anisotropic layer and a Hansen solubility parameter of the low-molecular-weight component in the pressure sensitive adhesive layer, and B represents a distance between a Hansen solubility parameter of a matrix component in the pressure sensitive adhesive layer and a Hansen solubility parameter of the low-molecular-weight component in the pressure sensitive adhesive layer.

Regarding the low-molecular-weight component having a molecular weight of 1,000 or less, in a case where the above-described condition 2 is satisfied, that is, in a case where the content of the low-molecular-weight component satisfying the expression (I) is 1.0% by mass or less with respect to the mass of the pressure sensitive adhesive layer, a content of a low-molecular-weight component satisfying “A≥B” is not particularly limited, but is usually 10% by mass or less in many cases.

In the present invention, the indentation modulus of the pressure sensitive adhesive layer is 0.4 to 6.0 MPa, but the lower limit value of the indentation modulus is preferably 0.5 MPa or more, more preferably more than 0.5 MPa, and still more preferably 0.6 MPa or more. In addition, the upper limit value of the indentation modulus is preferably 5.5 MPa or less, and more preferably 5.0 MPa or less.

Here, a method for adjusting the indentation modulus of the pressure sensitive adhesive layer is not particularly limited, and for example, a method of increasing the elastic modulus by performing a heat treatment can be adopted.

The pressure sensitive adhesive layer included in the laminate according to the embodiment of the present invention is preferably a pressure sensitive adhesive layer satisfying the above-described condition 1.

On the other hand, in a case where the pressure sensitive adhesive layer included in the laminate according to the embodiment of the present invention is a pressure sensitive adhesive layer satisfying the above-described condition 2, examples of the low-molecular-weight component having a molecular weight of 1,000 or less contained in the pressure sensitive adhesive layer include uncured products of the polymerization initiator and the binder (monomer component) used during the formation of the pressure sensitive adhesive layer. In addition, as the low-molecular-weight component, a component having no maximum absorption wavelength in the visible light region is preferable.

### <Polymer>

The pressure sensitive adhesive layer included in the laminate according to the embodiment of the present invention preferably contains a (meth)acrylic polymer, a silicone-based polymer, a urethane-based polymer, a vinyl alkyl ether-based polymer, a polyvinyl alcohol-based polymer, a polyvinylpyrrolidone-based polymer, a polyacrylamide-based polymer, or a cellulose-based polymer, and among these, it is preferable to contain a (meth)acrylic polymer.

In the present invention, from the viewpoint that the pressure sensitive adhesiveness is more favorable, it is preferable that the matrix component of the pressure sensitive adhesive layer is a (meth)acrylic polymer.

Here, the matrix component of the pressure sensitive adhesive layer refers to a component having the largest blending amount among components contained in the pressure sensitive adhesive layer.

Therefore, a content of the (meth)acrylic polymer is preferably more than 50% by mass and more preferably more than 70% by mass with respect to the mass of the pressure sensitive adhesive layer. The upper limit thereof may be determined in consideration of other components, and is usually 100% by mass or less, 99% by mass or less, or 95% by mass or less in many cases.

Examples of the (meth)acrylic polymer include a (meth)acrylic acid ester-based copolymer.

As the (meth)acrylic acid ester-based copolymer, a copolymer having a crosslinking point capable of being crosslinked by various crosslinking methods is used. There is no particular limitation on the (meth)acrylic acid ester-based copolymer having such a crosslinking point, and any copolymer can be appropriately selected and used from among (meth)acrylic acid ester-based copolymers commonly used as resin components of known pressure sensitive adhesives in the related art.

Suitable examples of the (meth)acrylic acid ester-based copolymer having such a crosslinking point include a copolymer of a (meth)acrylic acid ester in which an alkyl group of an ester moiety has 1 to 20 carbon atoms, a monomer having a crosslinking functional group in the molecule, and another monomer used as desired.

Here, examples of the (meth)acrylic acid ester in which the alkyl group of the ester moiety has 1 to 20 carbon atoms include methyl (meth)acrylate, ethyl (meth)acrylate, propyl (meth)acrylate, butyl (meth)acrylate, pentyl (meth)acrylate, hexyl (meth)acrylate, cyclohexyl (meth)acrylate, 2-ethylhexyl (meth)acrylate, isooctyl (meth)acrylate, decyl (meth)acrylate, dodecyl (meth)acrylate, myristyl (meth)acrylate, palmityl (meth)acrylate, and stearyl (meth)acrylate, and these may be used alone or in combination of two or more kinds thereof.

On the other hand, as the monomer having a crosslinking functional group in the molecule, for example, a monomer having at least one functional group selected from the group consisting of a hydroxyl group, a carboxyl group, an amino group, and an amide group is preferable; and specific examples thereof include (meth)acrylic acid hydroxyalkyl esters such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; (meth)acrylamides such as (meth)acrylamide, N-methyl (meth)acrylamide, and N-methylol (meth)acrylamide; (meth)acrylic acid monoalkylaminoalkyls such as monomethylaminoethyl (meth)acrylate, monoethylaminoethyl (meth)acrylate, monomethylaminopropyl (meth)acrylate, and monoethylaminopropyl (meth)acrylate; and ethylenically unsaturated carboxylic acids such as acrylic acid, methacrylic acid, crotonic acid, maleic acid, itaconic acid, and citraconic acid. These monomers may be used alone or in combination of two or more kinds thereof.

The copolymerization form of the (meth)acrylic acid ester-based copolymer is not particularly limited, and may be any of random, block, and graft copolymers.

In addition, a weight-average molecular weight of the (meth)acrylic acid ester-based copolymer is preferably 500,000 or more, more preferably 600,000 to 3,000,000, and still more preferably 1,900,000 to 2,500,000.

In addition, in the present invention, from the viewpoint of reducing changes in pressure sensitive adhesiveness depending on humidity, the HSP value of the matrix component of the pressure sensitive adhesive layer is preferably 18 or less, and more preferably 15 to 18.

The pressure sensitive adhesive layer included in the laminate according to the embodiment of the present invention is more preferably a layer formed of a composition for forming a pressure sensitive adhesive layer, containing the above-described polymer.

Here, the composition for forming a pressure sensitive adhesive layer may contain a binder, a polymerization initiator, a solvent, and the like described below in addition to the above-described polymer, as long as the pressure sensitive adhesive layer to be formed satisfies the above-described condition 1 or 2.

### <Binder>

Suitable examples of the binder include a polyfunctional (meth)acrylate-based monomer.

Specific examples of the polyfunctional (meth)acrylate-based monomer include bifunctional types such as 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol hydroxypivalate di(meth)acrylate, dicyclopentanyl di(meth)acrylate, caprolactone-modified dicyclopentenyl di(meth)acrylate, ethylene oxide-modified phosphoric acid di(meth)acrylate, di(acryloyloxyethyl)isocyanurate, and allylated cyclohexyl di(meth)acrylate; trifunctional types such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, and tris(acryloyloxyethyl)isocyanurate; tetrafunctional types such as diglycerin tetra(meth)acrylate and pentaerythritol tetra(meth)acrylate; pentafunctional types such as propionic acid-modified dipentaerythritol penta(meth)acrylate; and hexafunctional types such as dipentaerythritol hexa(meth)acrylate and caprolactone-modified dipentaerythritol hexa(meth)acrylate.

### <Polymerization Initiator>

Examples of the polymerization initiator include the same ones as described as the optional component of the composition for forming a light-absorbing anisotropic layer.

### <Solvent>

Examples of the solvent include the same ones as described as the optional component of the composition for forming a light-absorbing anisotropic layer.

A thickness of the pressure sensitive adhesive layer is not particularly limited, but from the viewpoint of thinning, it is preferably 25 μm or less, more preferably 15 μm or less, and still more preferably 5 μm or less. The lower limit thereof is not particularly limited, but is 0.1 μm or more in many cases.

In the present invention, from the viewpoint of improving the fissuring resistance, a ratio of the indentation modulus P of the light-absorbing anisotropic layer to the indentation modulus N of the pressure sensitive adhesive layer (elastic modulus P/elastic modulus N) is preferably 7,000 or less, more preferably 6,000 or less, and still more preferably 5,000 or less. In addition, the above-described ratio (elastic modulus P/elastic modulus N) is preferably 300 or more, more preferably 400 or more, and still more preferably 500 or more.

### [Other Members]

The laminate according to the embodiment of the present invention may include other members in addition to the light-absorbing anisotropic layer and the pressure sensitive adhesive layer described above.

Examples of the other members include a retardation layer, a reflective polarizer layer (for example, a cholesteric liquid crystal layer, a linear polarization-type reflective polarizer, and the like), a surface antireflection layer, a support (base material), and an alignment film.

(Retardation Layer Having Function of Converting Linearly Polarized Light into Circularly Polarized Light)

The retardation layer having a function of converting linearly polarized light into circularly polarized light (hereinafter, also simply referred to as “specific retardation layer”) is one kind of retardation layer.

The specific retardation layer is not particularly limited as long as it has a function of converting linearly polarized light into circularly polarized light, and examples thereof include a λ/4 plate.

The λ/4 plate is a plate having a λ/4 function, specifically, a plate having a function of converting linearly polarized light having a specific wavelength (preferably, visible light) into circularly polarized light (or converting circularly polarized light into linearly polarized light).

An in-plane retardation of the λ/4 plate at a wavelength of 550 nm is not particularly limited, but is preferably 120 to 150 nm, more preferably 125 to 145 nm, and still more preferably 135 to 140 nm.

In addition to the λ/4 plate, a retardation layer in which an in-plane retardation at a wavelength of 550 nm is 3/4 or 5/4 of a wavelength of any light of visible light is also preferable.

The specific retardation layer may have reverse wavelength dispersibility. The expression “having reverse wavelength dispersibility” denotes that as the wavelength increases, the value of the phase difference at the wavelength increases.

In addition, the specific retardation layer may have a multilayer structure, and specific examples thereof include a broadband λ/4 plate obtained by laminating a λ/4 plate and a λ/2 plate.

An angle formed by a slow axis of the specific retardation layer and an absorption axis of the light-absorbing anisotropic layer is not particularly limited, but is preferably within a range of 45°±10°.

The specific retardation layer may be a layer formed by immobilizing a liquid crystal compound twist-aligned with a thickness direction as a helical axis. For example, a retardation layer having a layer formed by immobilizing a rod-like liquid crystal compound or a disk-like liquid crystal compound twist-aligned with a thickness direction as a helical axis, as described in JP05753922B and JP05960743B, can be used.

A thickness of the specific retardation layer is not particularly limited, but is preferably 0.1 to 8 μm and more preferably 0.3 to 5 μm.

### <Positive C-Plate>

The positive C-plate is one type of retardation layer.

The positive C-plate is a retardation layer in which an in-plane retardation is substantially zero and a thickness-direction retardation has a negative value. The positive C-plate functions as an optical compensation layer for increasing the degree of polarization of the transmitted light with respect to light incident obliquely.

The in-plane retardation of the positive C-plate at a wavelength of 550 nm is preferably 10 nm or less.

The thickness-direction retardation of the positive C-plate at a wavelength of 550 nm is preferably −600 to −40 nm.

A material constituting the positive C-plate is not particularly limited, but it is preferable that the positive C-plate is formed of a composition containing a liquid crystal compound. Such a positive C-plate can be typically obtained by vertically aligning a rod-like polymerizable liquid crystal compound contained in the polymerizable liquid crystal composition and fixing the alignment state by polymerization. In addition, the positive C-plate can also be formed of a composition containing the side chain-type high-molecular-weight liquid crystal compound as the liquid crystal compound.

A thickness of the positive C-plate is not particularly limited, but from the viewpoint of thinning, it is preferably 0.5 to 10 μm and more preferably 0.5 to 5 μm.

### <Cholesteric Liquid Crystal Layer>

The cholesteric liquid crystal layer is an optical member which separates incidence ray into right-circularly polarized light and left-circularly polarized light, and specularly reflects one circularly polarized light and transmits the other circularly polarized light.

Examples of the cholesteric liquid crystal layer include a cholesteric liquid crystal layer obtained by fixing a cholesteric liquid crystalline phase. From the viewpoint that a decrease in degree of polarization and a distortion of a polarization axis are suppressed in a case of being stretched or formed into a three-dimensional shape, the cholesteric liquid crystal layer is preferably used as an optical film for curved surface forming. In addition, a decrease in degree of polarization due to the distortion of the polarization axis is unlikely to occur.

It is preferable that the cholesteric liquid crystal layer includes a blue light reflective layer in which at least reflectivity at a wavelength of 460 nm is 40% or more, a green light reflective layer in which a reflectivity at a wavelength of 550 nm is 40% or more, a yellow light reflective layer in which a reflectivity at a wavelength of 600 nm is 40% or more, and a red light reflective layer in which a reflectivity at a wavelength of 650 nm is 40% or more. With such a configuration, high reflection characteristics can be exhibited over a wide wavelength range in the visible region, which is preferable. The above-described reflectivity is a reflectivity in a case where non-polarized light is incident on the cholesteric liquid crystal layer at each wavelength.

In addition, the cholesteric liquid crystal layer may have a pitch gradient structure in which a helical pitch of the cholesteric liquid crystalline phase continuously changes in the thickness direction.

In addition, it is also preferable that a cholesteric liquid crystal layer obtained by fixing a cholesteric liquid crystalline phase containing a rod-like liquid crystal compound and a cholesteric liquid crystal layer obtained by fixing a cholesteric liquid crystalline phase containing a disk-like liquid crystal compound are used in combination as the cholesteric liquid crystal layer. In such a configuration, since the cholesteric liquid crystalline phase containing a rod-like liquid crystal compound has a positive Rth and the cholesteric liquid crystalline phase containing a disk-like liquid crystal compound has a negative Rth, the Rth of each other is offset, and thus the occurrence of the ghost can be suppressed even for the light incident from the oblique direction, which is preferable.

A thickness of the cholesteric liquid crystal layer is not particularly limited, but from the viewpoint of thinning, it is preferably 30 μm or less and more preferably 15 μm or less. The lower limit thereof is not particularly limited, but is 1 μm or more in many cases.

### <Linear Polarization-Type Reflective Polarizer>

The linear polarization-type reflective polarizer is a polarizer having a function of reflecting one linearly polarized light of linearly polarized light components orthogonal to each other, and allowing transmission of the other linearly polarized light components.

Examples of the linear polarization-type reflective polarizer include a film obtained by stretching a dielectric multi-layer film and a wire grid polarizer. Examples of the commercially available product include a reflective polarizer (trade name: APF) manufactured by 3M Company and a wire grid polarizer (trade name: WGF) manufactured by Asahi Kasei Corporation.

### <Surface Antireflection Layer>

The laminate according to the embodiment of the present invention may include a surface antireflection layer.

In the laminate according to the embodiment of the present invention, the surface antireflection layer is preferably disposed on the outermost surface side. The surface antireflection layer may be disposed only on one surface side of the laminate, or may be disposed on both surface sides of the laminate.

The type of the surface antireflection layer is not particularly limited, but from the viewpoint of further decreasing the reflectivity, a moth-eye film or an antireflection (AR) film is preferable. In addition, since the antireflection property can be maintained even in a case where the film thickness fluctuates due to stretching and forming, a moth-eye film is preferable.

An angle formed by a transmission axis of the linear polarization-type reflective polarizer and a transmission axis of the light-absorbing anisotropic layer is preferably within a range of 0° to 10°.

### <Support (Base Material)>

The laminate according to the embodiment of the present invention may include a support.

The support can be provided at any position, and for example, in a case where the cholesteric liquid crystal layer and the retardation layer are a film used by being transferred from the temporary support, the support can be used as a transfer destination thereof.

The type of the support is not particularly limited, but it is preferable that the support is transparent, and examples thereof include films made of cellulose acylate, polycarbonate, polysulfone, polyethersulfone, polyacrylate and polymethacrylate, cyclic polyolefin, polyolefin, polyamide, polystyrene, polyester, or the like. Among these, as the support, a cellulose acylate film, a cyclic polyolefin film, polyacrylate, a polyacrylate film, or a polymethacrylate film is preferable. In addition, commercially available cellulose acetate films (for example, “TD80U” or “Z-TAC” manufactured by FUJIFILM Corporation) can also be used.

In addition, it is preferable that the support has a small phase difference. Specifically, an in-plane retardation at a wavelength of 550 nm is preferably 10 nm or less, and an absolute value of the thickness-direction retardation at a wavelength of 550 nm is preferably 50 nm or less.

From the viewpoint of stretching and forming treatment, the support preferably has a tan δ peak temperature of 170° C. or lower. From the viewpoint that the forming can be performed at a low temperature, the tan δ peak temperature is preferably 150° C. or lower and more preferably 130° C. or lower.

Here, a method of measuring the tan δ will be described. E″ (loss elastic modulus) and E′ (storage elastic modulus) of a film sample which has been humidity-adjusted in advance in an atmosphere of a temperature of 25° C. and a humidity of 60% Rh for 2 hours or longer are measured under the following conditions using a dynamic viscoelasticity measuring device (DVA-200, manufactured by IT Measurement & Control Co., Ltd.), and the values are used to acquire tan δ (=E″/E′).
Device: DVA-200 manufactured by IT Measurement & Control Co., Ltd.
Sample: 5 mm, length of 50 mm (gap: 20 mm)
Measurement condition: Tensile mode
Measurement temperature: −150° C. to 220° C.
Heating conditions: 5° C./min
Frequency: 1 Hz

A thickness of the support is not particularly limited, and is preferably 5 to 300 μm, more preferably 5 to 100 μm, and still more preferably 5 to 30 μm.

### [Display Device]

The display device according to the embodiment of the present invention is a display device including the above-described laminate according to the embodiment of the present invention.

Examples of such a display device include a liquid crystal display device, an organic EL display device, and a virtual reality display device.

Some display devices are thin and can be formed into a curved shape. Since the laminate used in the present invention does not include an oxygen impermeable layer (barrier layer) and is thin and easily bent, it can be suitably applied to a display device having a curved display surface. Examples of such a curved surface include a curved surface in which a curvature radius of a portion having the smallest curvature is 20 mm or more and 300 mm or less.

### [Virtual Reality Display Device]

The FIGURE is a schematic view showing an example of a configuration of the virtual reality display device.

A virtual reality display device 80 shown in the FIGURE includes, from the right side in the drawing, an image display panel 82, a circularly polarizing plate 84, a half mirror 86, a lens 88, and a laminate 90 according to the embodiment of the present invention.

The composite lens is configured by the laminate 90, the lens 88, and the half mirror 86 shown in the FIGURE.

In the virtual reality display device 80 shown in the FIGURE, a ray 92 emitted from an image display panel 82 is transmitted through a circularly polarizing plate 84 to be circularly polarized light, and is transmitted through a half mirror 86. Next, the ray transmits through the lens 88, is incident from the side of the reflective polarizer layer (for example, the cholesteric liquid crystal layer) included in the laminate 90 according to the embodiment of the present invention, is reflected, transmits through the lens 88 again, is reflected by the half mirror 86 again, and is incident into the laminate 90 after being transmitted through the lens 88 again. In this case, the circular polarization state of the ray 92 does not change in a case where the ray 92 is reflected from the laminate 90, and changes to circular polarization having a turning direction opposite to that of the circular polarization incident on the laminate 90 in a case where the ray 92 is reflected from the half mirror 86. Therefore, the ray 92 is transmitted through the laminate 90, and visually recognized by a user. Furthermore, in a case where the ray 92 is reflected by the half mirror 86, since the half mirror has a concave mirror shape, the image is magnified so that the user can visually recognize the magnified virtual image. The system described above is referred to as a reciprocating optical system, a folded optical system, or the like.

The light-absorbing anisotropic layer included in the laminate 90 functions as a so-called linear polarizer, and is used to prevent light which is unnecessarily transmitted through the cholesteric liquid crystal layer from being observed by the user of the virtual reality display device as a leakage light (ghost).

The image display panel 82 is, for example, a known image display panel (display panel) such as an organic electroluminescence display panel.

In the example shown in the drawing, the image display panel 82 emits an image (image light) of unpolarized light. The unpolarized image emitted from the image display panel 82 passes through the circularly polarizing plate 84, and is converted into circularly polarized light.

### EXAMPLES

Hereinbelow, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention should not be restrictively interpreted by the following Examples.

### [Synthesis of Polymer (Matrix) Contained in Pressure Sensitive Adhesive Layer]

Butyl acrylate and butyl methacrylate were used in a mass ratio of 95:5 to synthesize, by a conventional method, a copolymer having a weight-average molecular weight of 2,000,000 and a molecular weight distribution (Mw/Mn) of 3.0. In addition, components having a molecular weight of 1,000 or less were removed from the above-described copolymer by purification to a level below the detection limit, and then the purified copolymer was used as a matrix. In Table 1 below, it is indicated as “Butyl acrylate/butyl methacrylate”.

### Example 1

### [Production of Base Material A1]

The following composition was put into a mixing tank, stirred, and heated at 90° C. for 10 minutes. Thereafter, the obtained composition was filtered through a filter paper having an average hole diameter of 34 μm and a sintered metal filter having an average hole diameter of 10 μm to prepare a dope. The concentration of solid contents of the dope was 23.5% by mass, the addition amount of the plasticizer was the ratio to the cellulose acylate, and the solvent of the dope was methylene chloride/methanol/butanol=81/18/1 (mass ratio).

Cellulose acylate dope

| | |
|---|---|
| Cellulose acylate (acetyl substitution degree of 2.86, | 100 parts by mass |
| viscosity average polymerization degree of 310) | |
| Sugar ester compound 1 (Formula (S4) | 6.0 parts by mass |
| shown below) | |
| Sugar ester compound 2 (Formula (S5) | 2.0 parts by mass |
| shown below) | |
| Silica particle dispersion liquid (AEROSIL R972, | 0.1 parts by mass |
| manufactured by Nippon Aerosil Co., Ltd.) | |
| Solvent (methylene chloride/methanol/butanol) | 351.9 parts by mass |

Sugar ester compound 1 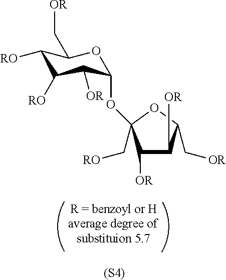
Sugar ester compound 2

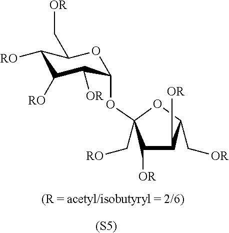

The produced dope above was cast using a drum film-forming machine. The dope was cast from a die such that it was in contact with a metal support cooled to 0° C., and then the obtained web (film) was stripped from the drum. The drum was made of stainless steel (SUS).

The web (film) obtained by casting was peeled off from the drum and dried in a tenter device for 20 minutes using a tenter device such that both ends of the web were clipped with clips and transported at 30° C. to 40° C. during film transport. Subsequently, the web was post-dried by zone heating while being rolled and transported. The obtained web was subjected to knurling and then wound up to obtain a base material A1.

In the obtained base material 1, a film thickness was 60 μm, an in-plane retardation Re(550) at a wavelength of 550 nm was 1 nm, and a thickness direction retardation Rth(550) at a wavelength of 550 nm was 35 nm.

### [Production of Photo-Alignment Film B1]

A composition B1 for forming a photo-alignment film, which will be described later, was continuously applied onto the above-described base material 1 with a wire bar. The support on which the coating film had been formed was dried with hot air at 140° C. and a wind speed of 1 m/s for 120 seconds, and the coating film was irradiated with polarized ultraviolet rays (10 mJ/cm², using an ultra-high pressure mercury lamp) to produce a photo-alignment film B1, thereby obtaining a base material 1 with a photo-alignment film. A film thickness of the photo-alignment film B1 was 1.5 km.

A concentration of solid contents of the composition B1 for forming a photo-alignment film was 20%, and a viscosity thereof was 3.5 mPa·s.

Formulation of composition B1 for forming photo-alignment film

| | |
|---|---|
| Polymer PA-1 (photo-alignment compound) shown below | 100.00 parts by mass |
| EPICLON N-695 (manufactured by DIC Corporation) | 55.74 parts by mass |
| jER YX7400 (manufactured by Mitsubishi Chemical Corporation) | 18.75 parts by mass |
| Polymer compound PB-1 shown below | 8.01 parts by mass |
| Thermal cationic polymerization initiator PAG-1 shown below | 16.75 parts by mass |
| Stabilizer DIPEA shown below | 1.06 parts by mass |
| Acid-cleavable surfactant SA-1 shown below | 0.50 parts by mass |
| Butyl acetate | 803 parts by mass |

Polymer PA-1 (photo-alignment compound) [weight-average molecular weight: 32,000; in the formula, numerical values described in each repeating unit represent a content (% by mass) of each repeating unit with respect to all repeating units] 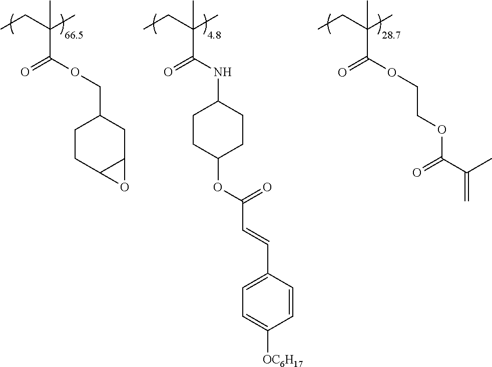
Thermal cationic polymerization initiator PAG-1 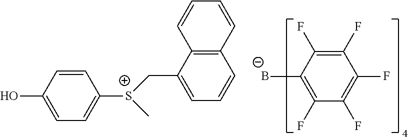
Stabilizer DIPEA 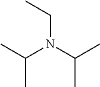
Polymer compound PB-1 (weight-average molecular weight: 18,000) 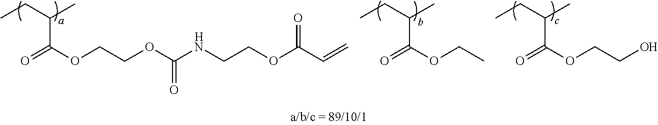
Acid-cleavable surfactant SA-1 [weight-average molecular weight: 78,000]

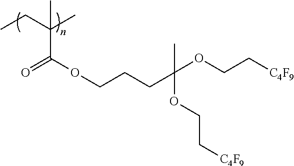

### [Formation of Light-Absorbing Anisotropic Layer C1]

A coating film was formed by continuously coating the obtained photo-alignment film B1 with a composition C1 for forming a light-absorbing anisotropic layer, having the following composition, with a wire bar.

Next, the coating film was heated at 140° C. for 15 seconds, was heated at 80° C. for 5 seconds, and was cooled to room temperature (23° C.). Next, the coating film was heated at 75° C. for 60 seconds and cooled again to room temperature.

Thereafter, the light-absorbing anisotropic layer C1 (polarizer) (thickness: 1.8 μm) was formed on the photo-alignment film B1 by performing irradiation with a light emitting diode (LED) lamp (central wavelength of 365 nm) under irradiation conditions of 300 mJ. The total content of the first dichroic substance Dye-C1, the second dichroic substance Dye-Mi, and the third dichroic substance Dye-Y1 contained in the light-absorbing anisotropic layer C1 was 220 mg/cm³.

In a case where a transmittance of the light-absorbing anisotropic layer C1 in a wavelength range of 280 to 780 nm was measured with a spectrophotometer, the average transmittance of visible light was 42%.

The absorption axis of the light-absorbing anisotropic layer C1 was in the plane of the light-absorbing anisotropic layer C1 and was orthogonal to the width direction of the base material A1.

Formulation of composition C1 for forming light-absorbing anisotropic layer

| | |
|---|---|
| First dichroic substance Dye-C1 shown below | 0.65 parts by mass |
| Second dichroic substance Dye-MI shown below | 0.15 parts by mass |
| Third dichroic substance Dye-Y1 shown below | 0.52 parts by mass |
| Liquid crystal compound L-1 shown below | 2.69 parts by mass |
| Liquid crystal compound L-2 shown below | 1.15 parts by mass |
| Adhesion improver A-1 shown below | 0.17 parts by mass |
| Polymerization initiator IRGACURE OXE-02 (manufactured by BASF SE) | 0.17 parts by mass |
| Surfactant F-1 shown below | 0.013 parts by mass |
| Cyclopentanone | 92.14 parts by mass |
| Benzyl alcohol | 2.36 parts by mass |

Dichroic substance Dye-C1 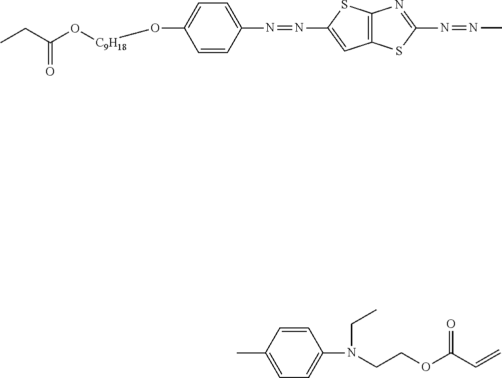
Dichroic substance Dye-M1 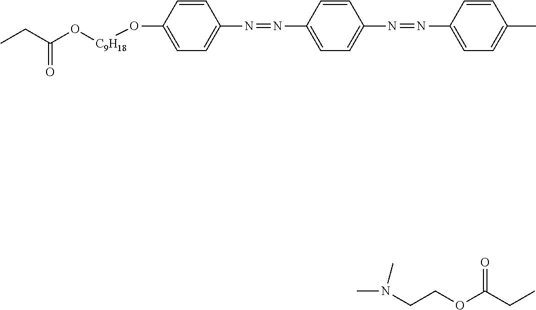
Dichroic substance Dye-Y1 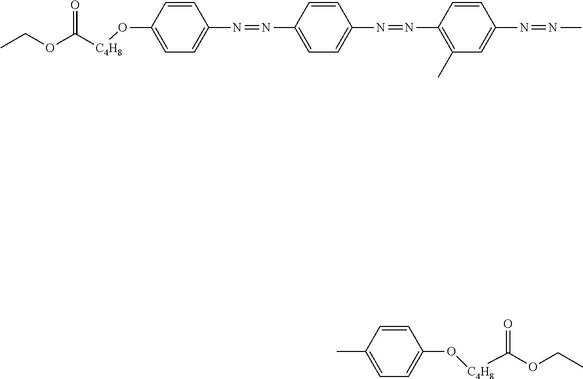
Liquid crystal compound L-1 [weight-average molecular weight: 18,000; in the formulae, numerical values (″59″, ″15″, ″26″) described in each repeating unit represent a content (% by mass) of each repeating unit with respect to all repeating units] 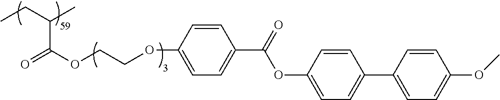 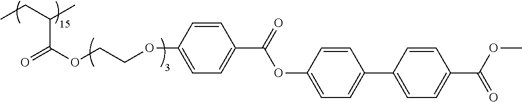 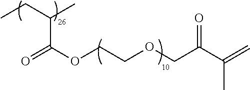
Liquid crystal compound L-2 [mixture of the following liquid crystal compounds (RA), (RB), and (RC) at a ratio of 84:14:2 (mass ratio)] 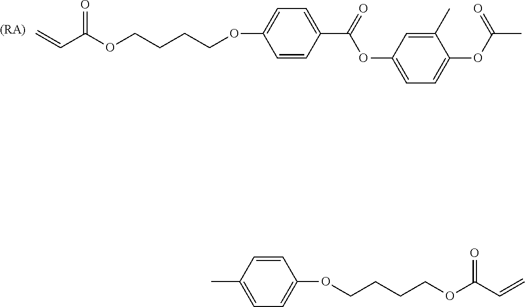 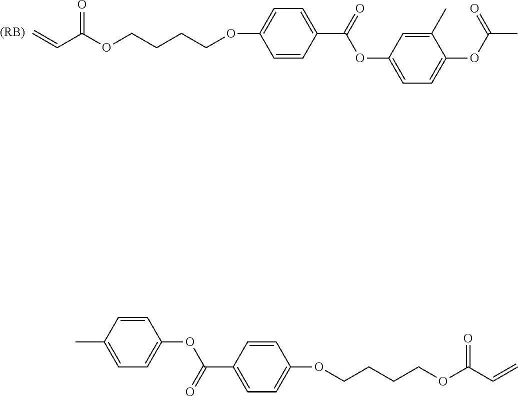 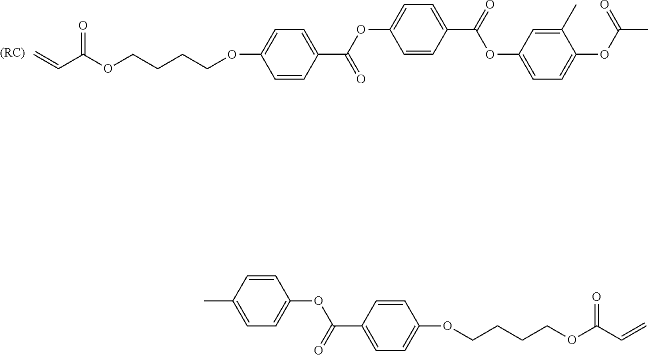
Adhesion improving agent A-1 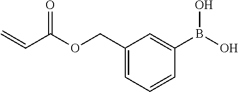
Surfactant F-1 [weight-average molecular weight: 15,000; in the formula, numerical values described in each repeating unit represent a content (% by mass) of each repeating unit with respect to all repeating units]

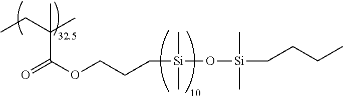

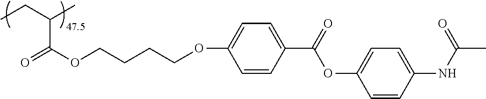

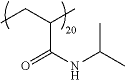

### [Production (Lamination) of Pressure Sensitive Adhesive Layer D1]

A composition for forming a pressure sensitive adhesive layer prepared with a composition shown in Table 1 below was applied onto a release layer of a polyethylene terephthalate release film (SP-PET3811 manufactured by Lintec Corporation) having a thickness of 38 μm as a release film with a knife coater, and then dried at 90° C. for 1 minute to form a pressure sensitive adhesive layer D1.

Next, the pressure sensitive adhesive layer D1 was laminated so as to be in contact with the surface of the previously produced light-absorbing anisotropic layer C1.

Next, 30 seconds after the lamination, ultraviolet rays (UV) were irradiated from the release film side under the following conditions, and then heat treatment was performed at 50° C. for 2 hours to obtain a laminate precursor (layer configuration: base material A1/photo-alignment film B1/light-absorbing anisotropic layer C1/pressure sensitive adhesive layer D1/release film).

Next, the release film was peeled off, and TG40 (manufactured by FUJIFILM Corporation) was laminated, and then the base material A1 was peeled off to obtain a laminate 1 (layer configuration: photo-alignment film B1/light-absorbing anisotropic layer C1/pressure sensitive adhesive layer D1/TG40).

As shown in Table 1 below, the laminate 1 did not contain a low-molecular-weight component having a molecular weight of 1,000 or less in the pressure sensitive adhesive layer D1.

### <UV Irradiation Conditions>

Using electrodeless lamp H bulb manufactured by Fusion UV Systems Inc.
Illuminance of 600 mW/cm², light intensity of 150 mJ/cm²

“UVPF-36” manufactured by Eye Graphics Co., Ltd. was used as a UV illuminance and light intensity meter.

### Example 2

A laminate 2 was produced in the same manner as in Example 1, except that the formulation of the composition for forming a pressure sensitive adhesive layer was changed to that shown in Table 1 below.

As shown in Table 1 below, the laminate 2 contained a low-molecular-weight component having a molecular weight of 1,000 or less in the pressure sensitive adhesive layer, but the content of the low-molecular-weight component satisfying “A<B” represented by the above expression (I) was 1.0% by mass or less.

### Example 3

A laminate 3 was produced in the same manner as in Example 1, except that the following light-absorbing anisotropic layer C2 was formed instead of the light-absorbing anisotropic layer C1.

As shown in Table 1 below, the laminate 3 did not contain a low-molecular-weight component having a molecular weight of 1,000 or less in the pressure sensitive adhesive layer D1.

### [Formation of Light-Absorbing Anisotropic Layer C2]

A composition C2 for forming a light-absorbing anisotropic layer was prepared with the following formulation, dissolved by heating at 80° C. for 2 hours with stirring, and filtered through a 0.45 μm filter.

Composition C2 for forming light-absorbing anisotropic layer

| | |
|---|---|
| Dichroic substance D1 shown below | 0.8 parts by mass |
| Dichroic substance D2 shown below | 2.6 parts by mass |
| Dichroic substance D3 shown below | 2.2 parts by mass |
| Dichroic substance D4 shown below | 1.8 parts by mass |
| Liquid crystal compound M-1 shown below | 100.0 parts by mass |
| Polymerization initiator IRGACURE 369 (manufactured by BASF) | 5.0 parts by mass |
| BYK361N (manufactured by BYK Chemie Japan Co., Ltd.) | 0.9 parts by mass |
| Cyclopentanone | 925.0 parts by mass |

Dichroic substance D1 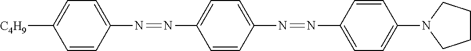
Dichroic substance D2 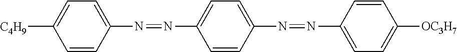
Dichroic substance D3 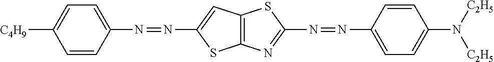
Dichroic substance D4 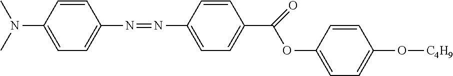
Liquid crystal compound M1 (mixture of compound A shown below/compound B shown below = 75/25)
(Compound A) 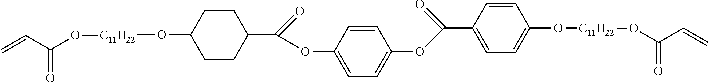
(Compound B)

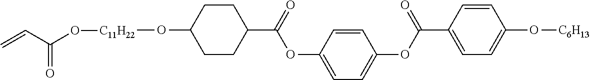

The above-described composition C2 for forming a light-absorbing anisotropic layer was applied onto the photo-alignment film B1 of a TAC (triacetyl cellulose) film with a photo-alignment film prepared in the same manner as in Example 1 with a wire bar. Next, the obtained coating film was heated at 120° C. for 60 seconds and cooled to room temperature.

Thereafter, the coating film was irradiated with ultraviolet rays at an exposure amount of 2,000 mJ/cm² using a high-pressure mercury lamp to form a light-absorbing anisotropic layer C2 having a thickness of 2.5 μm.

It was confirmed that the liquid crystal of the light-absorbing anisotropic layer C2 was a smectic B phase.

### Example 4

Using, as a thermoplastic resin base material, a long and amorphous isophthalate copolymer polyethylene terephthalate film (thickness: 100 μm) having a glass transition temperature of 75° C., one surface of the resin base material was subjected to a corona treatment.

A PVA-based resin (100 parts by mass) obtained by mixing polyvinyl alcohol (degree of polymerization: 4,200, degree of saponification: 99.2 mol %) and acetylated PVA (manufactured by Nippon Synthetic Chemical Industry Co., Ltd.; trade name: “Gosefimer”) at a ratio of 9:1 was dissolved in water to prepare a PVA aqueous solution (coating liquid) by adding 13 parts by mass of potassium iodide.

The PVA aqueous solution was applied to the corona-treated surface of the resin base material and dried at 60° C. to form a PVA-based resin layer having a thickness of 13 m, thereby producing a laminate.

The obtained laminate was uniaxially stretched 2.4 times in the machine direction (longitudinal direction) in an oven at 130° C. (air-assisted stretching treatment).

Next, the laminate was immersed in an insolubilization bath (boric acid aqueous solution obtained by mixing 4 parts by mass of boric acid with 100 parts by mass of water) at a liquid temperature of 40° C. for 30 seconds (insolubilization treatment).

Next, the laminate was immersed in a dyeing bath (iodine aqueous solution obtained by mixing iodine and potassium iodide at a mass ratio of 1:7 with respect to 100 parts by mass of water) at a liquid temperature of 30° C. for 60 seconds while adjusting the concentration (dyeing treatment).

Next, the laminate was immersed in a crosslinking bath (boric acid aqueous solution obtained by mixing 3 parts by mass of potassium iodide and 5 parts by mass of boric acid with respect to 100 parts by mass of water) at a liquid temperature of 40° C. for 30 seconds (crosslinking treatment).

Thereafter, the laminate was uniaxially stretched in the machine direction (longitudinal direction) between rolls having different circumferential speeds such that the total stretching ratio was 5.5 times while the laminate was immersed in a boric acid aqueous solution (boric acid concentration: 4% by mass, potassium iodide concentration: 5% by mass) at a liquid temperature of 70° C. (in-water stretching treatment).

Thereafter, the laminate was immersed in a washing bath (aqueous solution obtained by mixing 3 parts by mass of potassium iodide with 100 parts by mass of water) at a liquid temperature of 20° C. (washing treatment).

Thereafter, the laminate was brought into contact with a SUS heating roll of which the surface temperature was maintained at approximately 75° C. while being dried in an oven maintained at approximately 90° C. (drying contraction treatment).

In this manner, a light-absorbing anisotropic layer C4 was formed on the resin base material, and a laminate having a layer configuration of the resin base material and the light-absorbing anisotropic layer C4 was obtained.

Next, a pressure sensitive adhesive layer was laminated on the surface of the light-absorbing anisotropic layer C4 in the obtained laminate in the same manner as in Example 1; and 30 seconds after the lamination, ultraviolet rays (UV) were irradiated from the release film side under the same conditions as in Example 1, followed by heat treatment at 50° C. for 2 hours to obtain a laminate precursor (layer configuration: resin base material/light-absorbing anisotropic layer C4/pressure sensitive adhesive layer D1/release film).

Next, the release film was peeled off, and TG40 (manufactured by FUJIFILM Corporation) was laminated to obtain a laminate 4 (layer configuration: resin base material/light-absorbing anisotropic layer C4/pressure sensitive adhesive layer D1/TG40).

As shown in Table 1 below, the laminate 4 did not contain a low-molecular-weight component having a molecular weight of 1,000 or less in the pressure sensitive adhesive layer D1.

### Comparative Example 1

A laminate H1 was produced in the same manner as in Example 1, except that the heat treatment after the lamination of the pressure sensitive adhesive layer was not performed.

As shown in Table 1 below, the laminate H1 did not contain a low-molecular-weight component having a molecular weight of 1,000 or less in the pressure sensitive adhesive layer D1, but the indentation modulus of the pressure sensitive adhesive layer D1 was less than 0.4 MPa.

### Comparative Example 2

A laminate H2 was produced in the same manner as in Example 1, except that the formulation of the composition for forming a pressure sensitive adhesive layer was changed to that shown in Table 1 below.

As shown in Table 1 below, the laminate H2 contained more than 1.0% by mass of a low-molecular-weight component having a molecular weight of 1,000 or less in the pressure sensitive adhesive layer.

### Comparative Example 3

A laminate H3 was produced in the same manner as in Example 1, except that the formulation of the composition for forming a pressure sensitive adhesive layer was changed to that shown in Table 1 below.

As shown in Table 1 below, the laminate H3 contained more than 1.0% by mass of a low-molecular-weight component having a molecular weight of 1,000 or less in the pressure sensitive adhesive layer.

### Comparative Example 4

A laminate H4 was produced in the same manner as in Example 1, except that the composition for forming a pressure sensitive adhesive layer was changed to a commercially available product (NCF-D692, manufactured by Lintec Corporation).

As shown in Table 1 below, the laminate H4 contained more than 1.0% by mass of a low-molecular-weight component having a molecular weight of 1,000 or less in the pressure sensitive adhesive layer (NCF-D692).

### Comparative Example 5

A laminate H5 was produced in the same manner as in Example 3, except that the composition for forming a pressure sensitive adhesive layer was changed to a commercially available product (NCF-D692, manufactured by Lintec Corporation).

As shown in Table 1 below, the laminate H5 contained more than 1.0% by mass of a low-molecular-weight component having a molecular weight of 1,000 or less in the pressure sensitive adhesive layer (NCF-D692).

### Comparative Example 6

A composition H6 for forming a pressure sensitive adhesive layer shown below was prepared.

Composition H6 for forming pressure sensitive adhesive layer

| | |
|---|---|
| CEL2021P (manufactured by Daicel Corporation) shown below | 70 parts by mass |
| 1,4-Butanediol diglycidyl ether | 20 parts by mass |
| 2-Ethylhexyl glycidyl ether | 10 parts by mass |
| CPI-100P shown below | 2.25 parts by mass |

CEL2021P 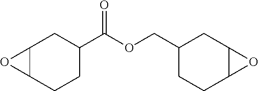 [SMILES: O=C(OCC1CCC2OC2C1)C1CCC2OC2C1]
CPI-100P

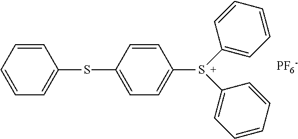

### <Production of Laminate H6>

A laminate up to the base material 1, the photo-alignment film B1, and the light-absorbing anisotropic layer C1 was produced in the same manner as in Example 1.

Next, the light-absorbing anisotropic layer C1 side of the produced laminate and TG40 (manufactured by FUJIFILM Corporation) were bonded together using the composition H6 for forming a pressure sensitive adhesive layer, and cured so that the indentation modulus became 6,000 MPa by adjusting the UV irradiation conditions.

Next, the base material A1 was peeled off to obtain a laminate H6 (layer configuration: photo-alignment film B1/light-absorbing anisotropic layer C1/pressure sensitive adhesive layer H6/TG40).

### [Evaluation]

### [Fissuring Resistance]

Fissuring resistance was evaluated by the following method in accordance with General test methods for paints—Bend resistance (cylindrical mandrel method) described in JIS-K-5600-5-1 (1999).

Specifically, after conditioning the produced laminates 1 to 4 and laminates H1 to H6 for 16 hours under conditions of 25° C. and 55% relative humidity, each of them was wound around a mandrel having a diameter (Φ) of 2, 3, 4, 5, 6, 8, 10, 12, 16, 20, 25, or 32 mm so that TG40 was on the outside, the state of occurrence of cracks was observed, and, in accordance with the following standard, fissuring resistance was evaluated by the minimum mandrel diameter at which cracks did not occur. The occurrence of cracks under the condition of a larger mandrel diameter indicates weaker fissuring resistance.

### <Evaluation Standard>

A: no cracks occurred even with a mandrel of 2 mm.
B: cracks occurred with a mandrel of 3 to 4 mm.
C: cracks occurred with a mandrel or 5 mm or more.

### [Pressure Sensitive Adhesiveness]

A cross-cut test (grid tape peeling test) in accordance with JIS D 0202-1988 was performed on the produced laminates 1 to 4 and laminates H1 to H6.

100 squares were formed by cutting from the TG40 side to the light-absorbing anisotropic layer in a grid pattern. Among the 100 squares formed, the number of peeled squares was counted by attaching and peeling off a cellophane tape (“CT24”, manufactured by Nichiban Co., Ltd.), and evaluation was performed according to the following standard.

### <Evaluation Standard>

A: the number of peeled squares was 0.
B: the number of peeled squares was 1 to 30.
C: the number of peeled squares was 31 or more.

### [Durability]

The produced laminates 1 to 4 and laminates H1 to H6 were left to stand for 500 hours in an environment of 80° C. and less than 10% relative humidity. Smaller change in transmittance before and after aging indicates better durability. The transmittance could be calculated from the average value of orthogonal transmittance and parallel transmittance in a wavelength range of 380 to 780 nm using a spectrophotometer (VAP-7070, manufactured by JASCO Corporation).

### <Evaluation Standard>

A: change in transmittance was less than 2%.
B: change in transmittance was 2% or more.

TABLE 1

| | | | | Composition for forming pressure sensitive adhesive layer | | | | | | | |
|---|---|---|---|---|---|---|---|---|---|---|---|
| | | | | | | | | | Photopo- | | |
| | Light-absorbing | | | | | | | | lymerization | | |
| | anisotropic layer | | | Matrix | | | Binder | | initiator | | |
| | Matrix | | Elastic | | | Part | | Part | | Part | Heat |
| | | HSP | modulus | | HSP | by | | by | | by | treat- |
| | Type | value | [MPa] | Type | Value | mass | Type | mass | Type | mass | ment |
| Example 1 | Liquid | 20.0 | 2550 | Butyl | 17.3 | 100 | None | 0 | None | 0.0 | 50° C. |
| | crystal | | | acrylate/butyl | | | | | | | 2 hours |
| | compound | | | methacrylate | | | | | | | |
| | L-1 | | | | | | | | | | |
| Example 2 | Liquid | 20.0 | 2550 | Butyl | 17.3 | 100 | Ditrimeth- | 15 | Irgacure 184 | 0.8 | 50° C. |
| | crystal | | | acrylate/butyl | | | ylolpropane | | | | 2 hours |
| | compound | | | methacrylate | | | tetraacrylate | | | | |
| | L-1 | | | | | | | | | | |
| Example 3 | Liquid | 21.2 | 3050 | Butyl | 17.3 | 100 | None | 0 | None | 0.0 | 50° C. |
| | crystal | | | acrylate/butyl | | | | | | | 2 hours |
| | compound | | | methacrylate | | | | | | | |
| | M-1 | | | | | | | | | | |
| Example 4 | PVA-based | 24.9 | 10000 | Butyl | 17.3 | 100 | None | 0 | None | 0.0 | 50° C. |
| | resin | | | acrylate/butyl | | | | | | | 2 hours |
| | | | | methacrylate | | | | | | | |
| Comparative | Liquid | 20.0 | 2550 | Butyl | 17.3 | 100 | None | 0 | None | 0.0 | None |
| Example 1 | crystal | | | acrylate/butyl | | | | | | | |
| | compound | | | methacrylate | | | | | | | |
| | L-1 | | | | | | | | | | |
| Comparative | Liquid | 20.0 | 2550 | Butyl | 17.3 | 100 | None | 0 | Irgacure 184 | 1.4 | 50° C. |
| Example 2 | crystal | | | acrylate/butyl | | | | | | | 2 hours |
| | compound | | | methacrylate | | | | | | | |
| | L-1 | | | | | | | | | | |
| Comparative | Liquid | 20.0 | 2550 | Butyl | 17.3 | 100 | Ditrimeth- | 15 | Irgacure 184 | 1.4 | 50° C. |
| Example 3 | crystal | | | acrylate/butyl | | | ylolpropane | | | | 2 hours |
| | compound | | | methacrylate | | | tetraacrylate | | | | |
| | L-1 | | | | | | | | | | |
| Comparative | Liquid | 20.0 | 2550 | NCF-D692 | | | | | | | 50° C. |
| Example 4 | crystal | | | | | | | | | | 2 hours |
| | compound | | | | | | | | | | |
| | L-1 | | | | | | | | | | |
| Comparative | Liquid | 21.2 | 3050 | NCF-D692 | | | | | | | 50° C. |
| Example 5 | compound | | | | | | | | | | 2 hours |
| | M-1 | | | | | | | | | | |
| Comparative | Liquid | 20.0 | 2550 | CEL2021P | 22.1 | 70 | 1,4-Butanediol | 20/10 | CPI-100P | 2.3 | 50° C. |
| Example 6 | crystal | | | | | | glycidyl | | | | 2 hours |
| | compound | | | | | | ether/2-ethylhexyl | | | | |
| | L-1 | | | | | | glycidyl ether | | | | |

| | Pressure sensitive adhesive layer | | | | | | |
|---|---|---|---|---|---|---|---|
| | Presence or | Low- | | | | | |
| | absence | molecular- | | | Performance | | |
| | of low- | weight | Inden- | | | Pressure | |
| | molecular- | component | tation | Mod- | Fissuring | sensitive | |
| | weight | satisfying | modulus | ulus | resis- | adhesive- | Dura- |
| | component | A < B | [MPa] | ratio % | tance | ness | bility |
| Example 1 | N | — | 0.6 | 3984 | A | B | A |
| Example 2 | Y | 0.7 wt % | 4.9 | 526 | A | A | A |
| Example 3 | N | — | 0.6 | 4766 | A | B | A |
| Example 4 | N | — | 0.6 | 15625 | B | B | A |
| Comparative | N | — | 0.3 | 8500 | B | C | A |
| Example 1 | | | | | | | |
| Comparative | Y | 1.4 wt % | 0.6 | 3984 | A | B | B |
| Example 2 | | | | | | | |
| Comparative | Y | 1.2 wt % | 10.0 | 255 | C | A | B |
| Example 3 | | | | | | | |
| Comparative | Y | 1.4 wt % | 9.7 | 263 | C | A | B |
| Example 4 | | | | | | | |
| Comparative | Y | 1.4 wt % | 9.7 | 314 | C | A | B |
| Example 5 | | | | | | | |
| Comparative | Y | 0.0 wt % | 6000.0 | 0 | C | A | A |
| Example 6 | | | | | | | |

* The modulus ratio represents “indentation modulus of light-absorbing anisotropic layer/indentation modulus of pressure sensitive adhesive layer”.

From the results shown in Table 1, it was found that, even in a case where the pressure sensitive adhesive layer adjacent to the light-absorbing anisotropic layer did not contain the low-molecular-weight component having a molecular weight of 1,000 or less, pressure sensitive adhesiveness was inferior as the indentation modulus was less than 0.4 MPa (Comparative Example 1), and it was found that fissuring resistance was inferior as the indentation modulus was more than 6.0 MPa (Comparative Example 6).

In addition, it was found that durability was inferior as the pressure sensitive adhesive layer adjacent to the light-absorbing anisotropic layer was a pressure sensitive adhesive layer containing more than 1.0% by mass of the low-molecular-weight component having a molecular weight of 1,000 or less (Comparative Examples 2 to 5), and among these, it was found that fissuring resistance was inferior as the indentation modulus was more than 6.0 MPa (Comparative Examples 3 to 5).

On the other hand, it was found that, in a case where the pressure sensitive adhesive layer adjacent to the light-absorbing anisotropic layer was a pressure sensitive adhesive layer having an indentation modulus of 0.4 to 6.0 MPa and in which the low-molecular-weight component having a molecular weight of 1,000 or less satisfied the above-described condition 1 or 2, the fissuring resistance, the pressure sensitive adhesiveness, and the durability were all favorable (Examples 1 to 4).

In particular, from the comparison between Examples 1 to 3 and Example 4, it was found that the fissuring resistance was more favorable as the ratio (indentation modulus P/indentation modulus N) of the indentation modulus P of the light-absorbing anisotropic layer to the indentation modulus N of the pressure sensitive adhesive layer (P/N) was 7,000 or less.

### EXPLANATION OF REFERENCES

80: virtual reality display device
82: image display panel
84: circular polarization plate
86: half mirror
88: lens
90: laminate
92: ray

What is claimed is:

1. A laminate comprising:
a light-absorbing anisotropic layer; and
a pressure sensitive adhesive layer provided adjacent to at least one surface of the light-absorbing anisotropic layer,
wherein the light-absorbing anisotropic layer contains a dichroic substance having a molecular weight of 1,000 or less,
an indentation modulus of the pressure sensitive adhesive layer is 0.4 MPa to 6.0 MPa, and
the pressure sensitive adhesive layer satisfies the following condition 1 or condition 2 with regard to a low-molecular-weight component having a molecular weight of 1,000 or less,
the condition 1: the pressure sensitive adhesive layer does not contain the low-molecular-weight component,
the condition 2: in a case where the pressure sensitive adhesive layer contains the low-molecular-weight component, a content of the low-molecular-weight component satisfying the following expression (I) is 1.0% by mass or less with respect to a mass of the pressure sensitive adhesive layer,
$$A < B \qquad ( I )$$
in the expression (I), A represents a distance between a Hansen solubility parameter of a matrix component in the light-absorbing anisotropic layer and a Hansen solubility parameter of the low-molecular-weight component in the pressure sensitive adhesive layer, and B represents a distance between a Hansen solubility parameter of a matrix component in the pressure sensitive adhesive layer and the Hansen solubility parameter of the low-molecular-weight component in the pressure sensitive adhesive layer.

2. The laminate according to claim 1, wherein the matrix component of the light-absorbing anisotropic layer is a liquid crystal compound.

3. The laminate according to claim 2, wherein the Hansen solubility parameter of the matrix component in the light-absorbing anisotropic layer is 18 or more.

4. The laminate according to claim 1, wherein the matrix component in the pressure sensitive adhesive layer is an acrylic or methacrylic polymer.

5. The laminate according to claim 4, wherein the Hansen solubility parameter of the matrix component in the pressure sensitive adhesive layer is 18 or less.

6. The laminate according to claim 1, wherein a ratio of an indentation modulus of the light-absorbing anisotropic layer to the indentation modulus of the pressure sensitive adhesive layer is 7,000 or less.

7. A display device comprising the laminate according to claim 1.

8. The laminate according to claim 1, wherein the Hansen solubility parameter of the matrix component in the light-absorbing anisotropic layer is 18 or more.

9. The laminate according to claim 2, wherein the matrix component in the pressure sensitive adhesive layer is an acrylic or methacrylic polymer.

10. The laminate according to claim 2, wherein the Hansen solubility parameter of the matrix component in the pressure sensitive adhesive layer is 18 or less.

11. The laminate according to claim 2, wherein a ratio of an indentation modulus of the light-absorbing anisotropic layer to the indentation modulus of the pressure sensitive adhesive layer is 7,000 or less.

12. A display device comprising the laminate according to claim 2.

13. The laminate according to claim 3, wherein the matrix component in the pressure sensitive adhesive layer is an acrylic or methacrylic polymer.

14. The laminate according to claim 3, wherein the Hansen solubility parameter of the matrix component in the pressure sensitive adhesive layer is 18 or less.

15. The laminate according to claim 3, wherein a ratio of an indentation modulus of the light-absorbing anisotropic layer to the indentation modulus of the pressure sensitive adhesive layer is 7,000 or less.

16. A display device comprising the laminate according to claim 3.

17. The laminate according to claim 1, wherein the Hansen solubility parameter of the matrix component in the pressure sensitive adhesive layer is 18 or less.

18. The laminate according to claim 4, wherein a ratio of an indentation modulus of the light-absorbing anisotropic layer to the indentation modulus of the pressure sensitive adhesive layer is 7,000 or less.

19. A display device comprising the laminate according to claim 4.

20. The laminate according to claim 1, wherein the Hansen solubility parameter of the matrix component in the pressure sensitive adhesive layer is 18 or less.
